(19) United States
(12) Patent Application Publication
(10) Pub. No.: US 2022/0239293 A1
(43) Pub. Date: Jul. 28, 2022

(54) PULSE GENERATOR FOR GENERATING FLUCTUATED VOLTAGE-SPIKE TRAINS

(71) Applicant: NATIONAL UNIVERSITY CORPORATION HOKKAIDO UNIVERSITY, Sapporo-shi (JP)

(72) Inventors: Seiya KASAI, Sapporo-shi (JP); Naoki SUEFUJI, Sapporo-shi (JP)

(21) Appl. No.: 17/583,182

(22) Filed: Jan. 24, 2022

(30) Foreign Application Priority Data
Jan. 28, 2021 (JP) 2021-012464

(51) Int. Cl. H03K 17/687; G06N 3/04

(52) U.S. Cl. CPC H03K 17/6872; G06N 3/049; H03K 17/6874

(57) ABSTRACT

A pulse generator encompasses an output circuit connected between a higher-potential power-supply and a lower-potential power-supply, and a voltage source for supplying an input voltage to the output circuit. The output circuit is implemented by a resistor-connected complementary transistor-circuit including a CMOS inverter, and a resistive element connected in series to the CMOS inverter, and the input voltage swings in a span including at least a simultaneous-conduction regime of the CMOS inverter, with respect to a swing-center potential set to an inverter threshold as a reference. A resistance value of the resistive element is selected such that a potential drop by the shoot-through current when the maximum value of the shoot-through current flows through the resistive element provide a deviation of the input voltage from the simultaneous-conduction regime. A train of spike-shaped pulses is delivered from the output circuit, by repeating process of conductions and interruptions of the shoot-through current.

### CROSS REFERENCE TO RELATED APPLICATIONS AND INCORPORATION BY REFERENCE

This application claims benefit of priority under 35 USC 119 based on Japanese Patent Application No. P2021-012464 filed Jan. 28, 2021, the entire contents of which are incorporated by reference herein.

### BACKGROUND OF THE INVENTION

### Field of the Invention

The present invention relates to a pulse generator that can generate fluctuated voltage-spike trains, which are suitable for neural network devices, quantum computers and others.

### Description of the Related Art

In recent years, as to the computer architectures for artificial intelligence (AI), there are some reports such that brain-inspired information-processing scheme referred as “spiking neuron” is a promising candidate as a high capability scheme to be used in AI computer architectures (for example, please refer to “NIKKEI ELECTRONICS”, 2020.07, pp. 56-62). A model that faithfully mimics the mechanism of the human-brain's nerve cells or neurons of a living body more and more is called “spiking neural network (SNN)”. In the SNN, information is transmitted by frequencies and timings of voltage-spikes and not by magnitudes or amplitudes of the voltage-spikes, inspired by the system of information transmission in the living body.

Also, in brain networks in human-brains, the greater the number of synapses—joints between the neurons—for a single neuron, or for a piece of information, denser the brain network. Therefore, higher and higher the density of the brain network, better and better the efficiency of information transmission, and then, a higher-level human-brain is realized. However, in order to realize a brain system comparable to brains of mammals, together with tens of millions to hundreds of millions, and even more neurons, it is necessary to connect tens of millions to tens of thousands of synapses to a single neuron. Such large scale of tens of millions of synapses means that an enormous amount of pulse generators, each of which generates a huge number of voltage spikes, must be merged in a single integrated circuit for realizing an advanced processing scheme with the SNN, which mimics the operations and functions in living body.

For example, G. Indiveri et al. have reviewed an electronic circuit, which mimics an axon-hillock of neurons as the electronic circuitry for generating the voltage spikes (please refer to G. Indiveri et al., “Neuromorphic Silicon Neuron Circuits”, Front. Neurosci., vol. 5, No. 73, 2011). However, in the neuromorphic silicon neuron circuits, when the frequency and timings of the voltage spikes are controlled, a circuit scale becomes very large. Thus, it is impossible to realize integrated circuits (chips) for realizing the AI computer architecture compatible to the brain of the mammals, as mentioned above. That is, in future, in order to further improve the information-processing capability of the AI computer architecture, and to install the integrated circuits in a mobile system such as a robot, it is desired to develop compact pulse generators having fewer elements than known technologies so that a great many pulse generators can be assembled in a computer system.

### SUMMARY OF THE INVENTION

An aspect of the present invention inheres in a pulse generator encompassing (a) an output circuit connected between a higher-potential power-supply and a lower-potential power-supply, the output circuit is implemented by a resistor-connected complementary transistor-circuit including a CMOS inverter, and a resistive element connected in series to the CMOS inverter, and (b) a voltage source for supplying an input voltage to the CMOS inverter, the input voltage swings in a span including at least a simultaneous-conduction regime of the CMOS inverter, with respect to a swing-center potential set to an inverter threshold as a reference. In the pulse generator pertaining to the aspect of the present invention, shoot-through currents flowing in the CMOS inverter is represented as a triangle in a current versus voltage characteristic diagram of the CMOS inverter, in which values of the input voltage to the CMOS inverter is indicated on a voltage axis of the current versus voltage characteristic diagram, a maximum value of the shoot-through current is defined as a height of the triangle, the inverter threshold is defined as a voltage providing the maximum of the shoot-through current, and the simultaneous-conduction regime is defined as a length of a bottom side of the triangle. And furthermore, in the pulse generator pertaining to the aspect of the present invention, a resistance value of the resistive element is selected such that a potential drop by the shoot-through current when the maximum value of the shoot-through current flows through the resistive element provide a deviation of the input voltage from the simultaneous-conduction regime, and a train of spike-shaped pulses is delivered from the output circuit, by repeating process of conductions and interruptions of the shoot-through current.

### BRIEF DESCRIPTION OF THE DRAWINGS

FIG. 1 is a block diagram illustrating a pulse generator pertaining to a first embodiment of the present invention;

FIG. 2 is a circuit diagram illustrating an outline of a CMOS inverter as an example of an output circuit in the pulse generator pertaining to the first embodiment;

FIG. 3 is a timing table illustrating each of time-series states of the resistor-connected complementary transistor-circuit, configured to explain a part of mechanisms for providing spike-train signals by the resistor-connected complementary transistor-circuit recited in FIG. 2;

FIG. 4 is a circuit diagram of a resistor-connected complementary transistor-circuit as the output circuit of the pulse generator according to an experimental example;

FIG. 5A is a view illustrating measured waveforms in the resistor-connected complementary transistor-circuit recited in FIG. 4;

FIG. 5B is an enlarged view of FIG. 5A illustrating an enlarged portion of the measured oscillation waveforms;

FIG. 6A is a circuit diagram illustrating a resistor-connected complementary transistor-circuit implemented by a double-stage CMOS inverter pertaining to a second embodiment of the present invention;

FIG. 6B is a circuit diagram illustrating an example of a complementary circuit implemented by a NAND gate;

FIG. 6C is a circuit diagram illustrating an example of a complementary circuit implemented by an AND gate;

FIG. 7 illustrates experimental results for explaining that a reproducibility (controllability) of the spike-train signals is improved by the output circuit recited in FIG. 6A;

FIG. 8 is a view illustrating simulation results of transmission characteristics and current characteristics of the CMOS inverter;

FIG. 9 illustrates measured data of the transmission characteristics and current characteristics of the CMOS inverters;

FIG. 10 is a diagram illustrating power-supply voltage vs. shoot-through current characteristics of the resistor-connected complementary transistor-circuit, which implements the output circuit;

FIG. 11 is a diagram illustrating relationships between resistive values and input voltages of resistive elements, according to the pulse generator pertaining to the second embodiment;

FIG. 12 is a block diagram illustrating a part of a neural network, as an application example of the pulse generator pertaining to the first embodiment;

FIG. 13 is a flowchart illustrating an example of basic operations of a first neuron circuit recited in FIG. 12; and.

FIG. 14 is a schematic circuit diagram illustrating an outline of an amoeba computer embracing octuple pseudopodia-units, to which the pulse generators pertaining to the first and second embodiment are applied, configured to generate the fluctuations by the mechanism of the amoeba computer.

### DETAILED DESCRIPTION OF THE INVENTION

In general, when a voltage at levels of intermediate values (hereafter, referred as “intermediate-level potential”) of an inter-terminal voltage of a CMOS inverter, or a voltage near the intermediate-level potential is applied to an input terminal of the CMOS inverter, because a pMOS transistor and an nMOS transistor are turned on simultaneously, a phenomenon that a shoot-through current flows in the CMOS inverter occurs. As recited in Texas Instruments, output voltages are uncertain and become unstable when the shoot-through current flows (refer to White Paper of Texas Instruments Inc., SLLA364a, April 2017-May 2017 Revision). However, the present inventors have studied carefully the behaviors of simultaneous-conductive states very hard, and finally, have found that the oscillations caused by the simultaneous-conductive state, which were previously avoided as unstable oscillations, can be used and exploited as “a controlled spontaneous spike-train signal”.

Hereafter, first and second embodiments are exemplified as a technology in which the oscillations caused by the simultaneous-conductive state that were conventionally considered to be unstable can be utilized and leveraged as the controlled spike-train signal. In the description of the drawings, the identical or similar parts are denoted by the identical or similar reference numerals, and redundant descriptions thereof will be omitted. However, the drawings are schematic, and the relationship between the thickness and the plane dimensions, the ratio of the thickness of each layer, etc., may be different from the actual one. In addition, dimensional relations and ratios may also differ between the drawings.

Further, the first and second embodiments illustrated below exemplify the apparatus and methods for embodying the technical idea of the present invention, and the technical idea of the present invention does not specify the material, shape, structure, arrangement, or the like of the components as follows.

### First Embodiment

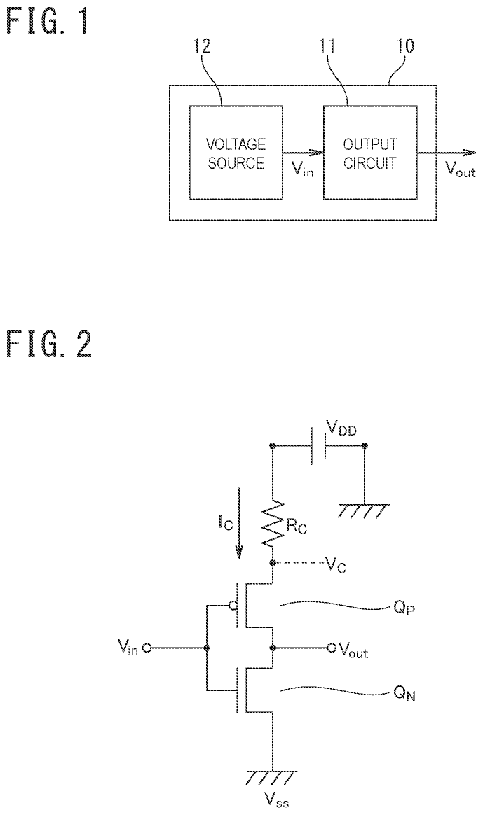

As illustrated in FIG. 1, a pulse generator 10 pertaining to a first embodiment of the present invention encompasses an output circuit 11, which can provide spike-train signals as output voltages Vₒᵤₜ, and a voltage source 12 for supplying specific input voltages Vᵢₙ to the output circuit 11. The output circuit 11 embraces “a resistor-connected complementary transistor-circuit” illustrated in FIG. 2. The resistor-connected complementary transistor-circuit includes a CMOS inverter, which is a complementary circuit whose lower voltage side terminal is connected to a lower-potential power-supply V_{SS}, and a resistive element R_{C} connected between a higher-potential power-supply V_{DD} and a higher voltage side terminal of the complementary circuit. The complementary circuit in the pulse generator pertaining to the first embodiment is implemented by a single-stage CMOS inverter, and the single-stage CMOS inverter is implemented by a pMOS transistor Q_{P} whose source terminal (source electrode), which serves as the higher voltage side terminal of the CMOS inverter, is connected to the resistive element R_{C}, and an nMOS transistor Q_{N}, of which a drain terminal (drain electrode) is connected to a drain terminal of the pMOS transistor Q_{P}. A source terminal of the nMOS transistor Q_{N}, which serves as the lower voltage side terminal of the CMOS inverter, is connected to the lower-potential power-supply V_{SS}.

According to the pulse generator pertaining to the first embodiment, a connection node between the resistive element R_{C} and the source terminal of the pMOS transistor Q_{P} is defined as “a higher-potential side node V_{C}”, in the configuration of the resistor-connected complementary transistor-circuit illustrated in FIG. 2. An electric connection node between a gate terminal (gate electrode) of the pMOS transistor Q_{P} and a gate terminal (gate electrode) of the nMOS transistor Q_{N} implements an input terminal of the CMOS inverter. The higher-potential power-supply V_{DD} is, for example, the power supply of a positive potential V_{DD}, and the lower-potential power-supply V_{SS} is, for example, a ground potential (=0 volt). In a normal using method of a CMOS inverter, pulses having an amplitude of a rated inter-terminal voltage of the CMOS inverter, or pulsating waves having amplitude voltage (peak value)=input voltage Vᵢₙ, are entered to the input terminal of the CMOS inverter, and the CMOS inverter is accordingly made to act as an inverter, or NOT gate.

That is, the pulse generator pertaining to the first embodiment does use very consciously an intermediate-level potential (≈a simultaneous-conduction voltage) V_{1/2} of the CMOS inverter, which is typically inhibited when the CMOS inverter is used, and conversely ventures to use “potentials lying in a specific limited latitude” as the input voltage Vᵢₙ of the CMOS inverter at predetermined timings. As a result, it is possible to establish the pulse generator that can control a spike train frequency with simple and compact circuit topology, and therefore, a great number of the pulse generators can be easily installed in a complex computer system. In order to control operations caused by the inflows of the shoot-through currents that were conventionally considered to induce unstable oscillations, the voltage source 12 in the pulse generator 10 pertaining to the first embodiment has speculated various voltage drops caused by the resistive element R_{C}, and defines “a swing-center potential V_{th_c}” as represented by following Eq. (1):

Vᵢₙ=V_{th_c}+½(ΔVₜₕ₀+ΔVₙₒₙ₋ₒₛ) cos (ωt) (1).

Defining the swing-center potential V_{th_c} in Eq. (1) at a middle of voltage swings, and by feeding the input voltage Vᵢₙ, which swings with minute amplitudes within a range between an upper limit value (V_{th_c}+ΔV_{th0/2}) and a low limit value (V_{th_c}−ΔV_{th0/2}) of a simultaneous-conduction regime ΔVₜₕ₀, to the resistor-connected complementary transistor-circuit pertaining to the first embodiment, it is possible to generate the spike-train signals of which a pulse width and a frequency are controlled.

As well known, an inverter threshold Vₜₕ of a CMOS inverter can be represented by following Eq. (2):

$${V}_{th} = \frac{{V}_{C} - \vert {V}_{th\_p} \vert + {V}_{th\_n} \sqrt{{β}_{n} / {β}_{p}}}{1 + \sqrt{{β}_{n} / {β}_{p}}} \qquad ( 2 )$$

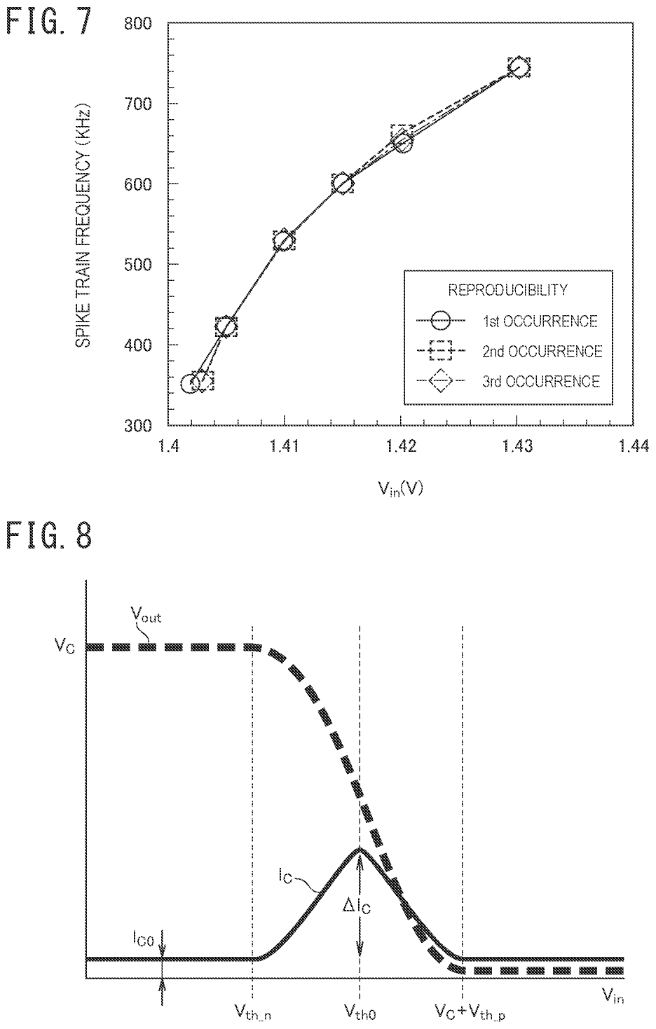

In a case of the usual CMOS inverter, the inverter threshold Vₜₕ is defined on an I-V characteristics diagram illustrated FIG. 8, which will be referred later. Namely, delineating a triangle as represented by a solid line in FIG. 8, the inverter threshold Vₜₕ is defined on a voltage axis of the I-V characteristics diagram, such that the inverter threshold Vₜₕ is a voltage at which a vertical line passing through an apex of the triangle crosses the voltage axis. In Eq. (2), V_{th_p} is a gate threshold voltage of the pMOS transistor Q_{P}, and V_{th_n} is a gate threshold voltage of the nMOS transistor Qₙ. Also, ßₚ is a coefficient that determines drain current versus drain voltage characteristics in a saturation region of the pMOS transistor Q_{P} as represented by Eq. (9b), which will be explained later. Similarly, ßₙ is a coefficient that determines drain current versus drain voltage characteristics in a saturation region of the nMOS transistor Q_{N} as represented by Eq. (9a), which will be explained later. Each of ßₚ and ßₙ is a parameter based on element structures, such as a thickness of a gate insulating film, a gate length and others. In a case of silicon (Si), the electron mobility μₙ is about three times the hole mobility μₕ. Thus, when the pMOS transistor Q_{P} and the nMOS transistor Q_{N} are assumed to be perfectly equal in various element structures such as the thickness of the gate insulating film and others, (ßₙ/ßₚ)^{1/2}=1.73 in Eq. (2).

The input voltages Vᵢₙ, for which the pMOS transistor Q_{P} and the nMOS transistor Q_{N} are scheduled to be turned on simultaneously, has a span corresponding to a width defined by a specific limited latitude, as illustrated in the triangle delineated by the solid line in FIG. 8. And therefore, the input voltages Vᵢₙ for simultaneous conduction is not a voltage value at a point given by the inverter threshold Vₜₕ. The swing-center potential V_{th_c} represented in the first term on the right side of Eq. (1) is a direct current (DC) component. Although the swing-center potential V_{th_c} in the first term on the right side of Eq. (1) may be determined by a voltage based upon the inverter threshold Vₜₕ, when the shoot-through current flows through the usual CMOS inverter, the swing-center potential V_{th_c} is a voltage that shall be corrected and adjusted, as represented by Eq. (7a), which will be explained later. As can be understood from Eq. (2), the inverter threshold Vₜₕ is not based on the resistor value of the resistive element R_{C}. To the contrary, the swing-center potential V_{th_c} in the first term on the right side of Eq. (1) is a value based on the resistor values of the resistive elements R_{C}, although the swing-center potential V_{th_c} is defined as a value when the shoot-through current does not flow through the resistive element R_{C}.

The simultaneous-conduction regime ΔVₜₕ₀ implements a part of an amplitude of an alternating current (AC) component cos (ωt) represented in the second term on the right side in Eq. (1). The simultaneous-conduction regime ΔVₜₕ₀ is a voltage span corresponding to a length of a bottom side of the triangle delineated by the solid line in FIG. 8, and a voltage represented by Eq. (25a), which will be explained later. An additional wingspan ΔVₙₒₙ₋ₒₛ implements extended another part of the amplitude of the AC component cos (ωt) of the second term on the right side in Eq. (1). The additional wingspan ΔVₙₒₙ₋ₒₛ is a voltage span corresponding to a width of a supplemental region collateral to both sides of the bottom side in the triangle delineated by the solid line in FIG. 8. The actual additional wingspan ΔVₙₒₙ₋ₒₛ is divided into two. Then, ΔVₙₒₙ₋ₒₛ/2 is extended toward a higher-potential power-supply side of the simultaneous-conduction regime ΔVₜₕ₀, and ΔVₙₒₙ₋ₒₛ/2 is extended toward a lower-potential power-supply side of the simultaneous-conduction regime ΔVₜₕ₀. The additional wingspan ΔVₙₒₙ₋ₒₛ that becomes the total width of the two halved ΔVₙₒₙ₋ₒₛ/2+ΔVₙₒₙ₋ₒₛ/2 may be selected as about ⅓ to two times of the simultaneous-conduction regime ΔVₜₕ₀, preferably about ½ to ⅚ times. The meaning of the AC component of the second item on the right side in Eq. (1) lies in a condition such that the amplitude of the input voltage Vᵢₙ shall swing in between a maximum value and a minimum value, the maximum value and the minimum value are defined as the upper and lower edges of the additional wingspan ΔVₙₒₙ₋ₒₛ, as the amplitude of the input voltage Vᵢₙ swings to extend over the span of the simultaneous-conduction regime ΔVₜₕ₀ toward regions in the span of the additional wingspan ΔVₙₒₙ₋ₒₛ in the output circuit 11 pertaining to the first embodiment.

A shoot-through current will flow through the CMOS inverter, as input voltages Vᵢₙ represented by Eq. (1) are applied to the gate terminal of the pMOS transistor Q_{P} and the gate terminal of the nMOS transistor Q_{N}, and when the potential of the input voltage Vᵢₙ is plunged into “an oscillation-drive active (ODA) range” defined in the span of the simultaneous-conduction regime ΔVₜₕ₀, according to the circuit topology of the resistor-connected complementary transistor-circuit illustrated in FIG. 2. When the shoot-through current flows through the CMOS inverter, the potential of the higher-potential side node V_{C} is decreased owing to a resistance value of the resistive element R_{C}. Thus, the resistive element R_{C} is an important component for the operation of the pulse generator pertaining to the first embodiment. For carry out the operations of the pulse generator to generate the voltage-spike trains, the alternating speeds in the AC component cos (ωt) of the second term on the right side in Eq. (1) are required to be sufficiently slower than the switching speeds of each of the pMOS transistor Q_{P} and the nMOS transistor Q_{N}. Moreover, the alternating speed in the shoot-through current of the resistor-connected complementary transistor-circuit illustrated in FIG. 2 and the alternating speed in the potential at the higher-potential side node V_{C} associated with the change of the shoot-through current is required to be approximately equal to the switching speeds of each of the pMOS transistor Q_{P} and the nMOS transistor Q_{N}, or faster than the switching speeds of each of the pMOS transistor Q_{P} and the nMOS transistor Q_{N}.

With regard to the resistance values of the resistive elements R_{C}, together with the conditions of the switching speeds, the potential drops of the higher-potential side node V_{C}, which are caused by the inflow of the shoot-through current, are required to comply with predetermined conditions. The values of the swing-center potentials V_{th_c} represented in the first term on the right side in Eq. (1) may be the fixed values that are predetermined by the resistance values of the resistive elements R_{C} or may be the variable values that can be set in view of the resistance values of the resistive elements R_{C}. For determining the swing-center potentials V_{th_c} as the variable values based on the resistance values of the resistive elements R_{C}, the voltage source 12 will prepare a lookup table (LUT), which indicates a relationship between the resistance values of the resistive elements R_{C} and the simultaneous-conduction voltages of the CMOS inverters from pre-performed experiments, and the values of the swing-center potentials V_{th_c}, can be determined depending on the LUT.

In actuality, situations that voltages at both ends of the bottom side in the triangle exhibited in FIG. 8, which indicates the simultaneous-conduction regime ΔVₜₕ₀ in Eq. (1), are insufficient to turn on the pMOS transistor Q_{P} and the nMOS transistor Q_{N} simultaneously, occur in many cases. Especially, the role of the potential drops in the higher-potential side node V_{C}, which are caused by the inflows of the shoot-through currents to the resistive element R_{C}, is important in the pulse generator pertaining to the first embodiment. Therefore, amount of the shoot-through current is required to be larger values close to the peak value (maximum value) ΔI_{C}, which flows through the resistive element R_{C}. The peak value (maximum value) ΔI_{C} of the shoot-through current is indicated as the height of the apex of the triangle exhibited in FIG. 8. So, “an effective drive span ΔV_{osc}” serving as the ODA range, in which the CMOS inverters effectively turn on simultaneously so that the potential of the higher-potential side node V_{C} can oscillate, is limited to a span narrower than the length of the bottom side in the triangle exhibited in FIG. 8, in the circuit topology of the resistor-connected complementary transistor-circuit. The effective drive span ΔV_{osc} is defined as a narrower specific length of a bottom side in a format of Eq. (19a), which will be explained later, by using “an effective-drive-span setting (EDSS) coefficient A” that is a coefficient experimentally defined. Thus, Eq. (1) defining the input voltage Vᵢₙ, which is used in the pulse generator pertaining to the first embodiment, is represented by Eq. (3), by using the effective drive span ΔV_{osc}.

Vᵢₙ=V_{th_c}+(½)(ΔV_{osc}+ΔVₙₒₙ₋ₒₛ) cos (ωt) (3)

The swing-center potential V_{th_c} in Eq. (3) is the voltage determined in view of the inverter threshold Vₜₕ₀, and the swing-center potential V_{th_c} typically differs from the inverter threshold Vₜₕ₀ as explained in Eq. (1). In Eq. (1), although the input voltage Vᵢₙ is explained as the voltage that swings at least within the simultaneous-conduction regime ΔVₜₕ₀ with respect to the swing-center potential V_{th_c}, the input voltage Vᵢₙ demonstrated in Eq. (3) swings in such a way that the effective drive span ΔV_{osc} serves as the ODA range of the CMOS inverter. According to the pulse generator pertaining to the first embodiment, the input voltage Vᵢₙ being swinging in the ODA range is supplied to the input terminal of the CMOS inverter. The sum of the effective drive span ΔV_{osc} and the additional wingspan ΔVₙₒₙ₋ₒₛ is assumed to be smaller than ½ of a voltage V_{C0} of an original higher-potential side node V_{C} in which the shoot-through current does not flow through the resistive element R_{C}, as represented by Eq. (4a):

ΔV_{osc}+ΔVₙₒₙ₋ₒₛ<V_{C0}/2 (4a).

In many cases, because the experimentally defined EDSS coefficient A is about seven to fifteen, the following Eq. (4b) is approximated:

ΔV_{osc}<<V_{C0}/2 (4b).

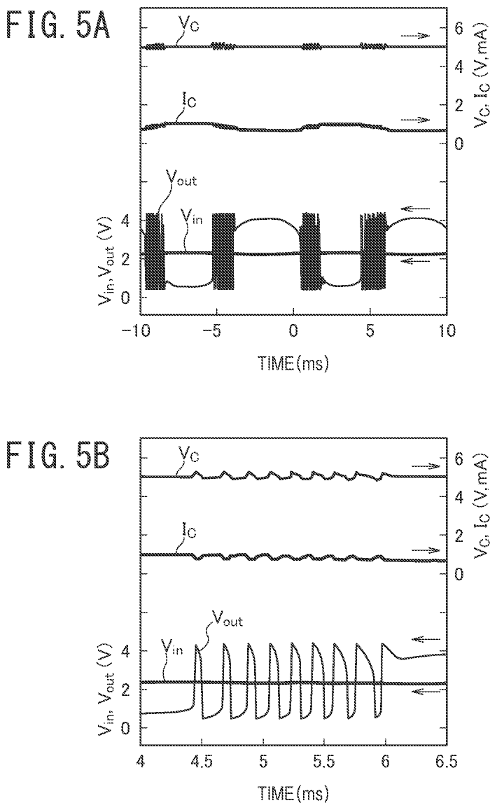

Also, the pulse trains may be steadily generated by setting the additional wingspan ΔVₙₒₙ₋ₒₛ=0, if the pulse generator pertaining to the first embodiment is not supposed to be in an intermittent mode, in which pulse trains are intermittently generated as wavelets after inverter intermission periods as illustrated in FIG. 5A, which will be explained later. In a case that the intermittent pulse trains of the wavelet shape are not generated, if the effective drive span ΔVₜₕ₀ is replaced to the effective drive span ΔV_{osc} serving as the ODA range, Eq. (3) can be represented by following Eq. (5a):

Vᵢₙ=V_{th_c}+(½)(ΔV_{osc}) cos (ωt) (5a)

ΔV_{osc}≤ΔVₜₕ₀ (5b).

The value of the effective drive span ΔV_{osc} in Eq.s (5a) and (5b) belongs to the ODA range in which the CMOS inverter is driven in such a way that spike-shaped pulse voltage trains are delivered from the output circuit 11 by turning on and off the shoot-through currents, and the ODA range may be indicated as a value sufficiently smaller than the simultaneous-conduction regime ΔVₜₕ₀.

ΔV_{osc}<<ΔVₜₕ₀ (5c)

Eq. (5c) means that, the voltage source 12 can transmit the input voltage Vᵢₙ in such a way that an amplitude of an AC component, superimposed on a DC component of the input voltage Vᵢₙ, swings in a span sufficiently smaller than the simultaneous-conduction regime ΔVₜₕ₀, when the intermittent mode as illustrated in FIG. 5A is not targeted. As can be understood from later-described explanations, as well as Eqs. (5b) and (5c), by setting an amplitude variation ΔV_{osc}/2 in the ODA range implemented by the AC component superimposed on the DC component of the input voltage Vᵢₙ to a minute amplitude variation of the ODA range in a span smaller than the simultaneous-conduction regime ΔVₜₕ₀/2, it is possible to carry out a control such that a pulse width of a spike pulse swings in a narrower range. Moreover, as a limit in which the values of the effective drive spans ΔV_{osc} in Eq. (5a) is minimized, a constant voltage supply of DC voltage, in which the voltage source 12 supplies only the DC voltage of the swing-center potential V_{th_c} as a fixed value, can be provided. In a case that the voltage source 12 supplies the DC voltage, the pulse generator pertaining to the first embodiment becomes an oscillator. In a case that the voltage source 12 supplies the DC voltage on which the AC voltage is superimposed, the pulse generator pertaining to the first embodiment becomes an AD converter of pulse width modulation (PWM) scheme. In addition, in a case that the voltage source 12 is used as the constant voltage supply of DC voltage, if the DC voltage delivered from the constant voltage supply is made to have ripple components, the spike-train signals delivered by the output circuit 11 can have fluctuating components. Even if variation caused by thermal noise is superimposed on the DC voltage delivered from the constant voltage supply, the spike-train signals delivered by the output circuit 11 can be made to have the fluctuating components. The fluctuating component includes variation at a rising timing of the spike pulse—which is hereafter referred to as “a pulse-firing timing”—.

V_{C} represented in the first term of the component on the right side in Eq. (2) corresponds to a power-supply voltage of a usual CMOS inverter and is a fixed value. However, in the circuit topology of the resistor-connected complementary transistor-circuit illustrated in FIG. 2, V_{C} can be values of swinging values, correspondingly to the potentials V_{C} of the higher-potential side node V_{C}. That is, in the pulse generator pertaining to the first embodiment, since the inverter threshold Vₜh is based on the voltage V_{C} of the higher-potential side node V_{C} illustrated in FIG. 2, Eq. (2) can be represented as a function of the voltage V_{C}, as represented by following Eq. (6):

Vₜₕ=f(V_{C}) (6).

As can be understood from the technical content on the right side in Eq. (2), attention should be paid to a subject matter that the inverter threshold Vₜₕ is not always equal to an intermediate value V_{C}/2 of the higher-potential side node V_{C}. For example, if (ßₙ/ßₚ)^{1/2}=1.73 and |V_{th_p}|=V_{th_n}=1.5 volts are assumed, at a condition of V_{C}=5 volts, the inverter threshold becomes Vₜₕ=2.23 volts from Eq. (2). Thus, the inverter threshold Vₜₕ is a value lower than V_{C}/2=2.5 volts. Only in a case of ßₙ=ßₚ and |V_{th_p}|=V_{th_n}, the inverter threshold becomes Vₜₕ=V_{C}/2. Moreover, in the configuration of the resistor-connected complementary transistor-circuit illustrated in FIG. 2, the voltages of the higher-potential side node V_{C} are variables that induce potential drops caused by the resistive element R_{C}, depending on the conductive states of the pMOS transistor Q_{P} and the nMOS transistor Q_{N}. According to the pulse generator pertaining to the first embodiment, the inverter threshold Vₜₕ is known to be not a constant value, as illustrated by Eq. (6).

In light of Eq. (6), in the explanation of the pulse generator pertaining to the first embodiment, the inverter threshold Vₜₕ corresponding to the voltage V_{C0} on the original higher-potential side node V_{C} when the shoot-through current does not flow through the resistive element R_{C} is defined as “no-load inverter-threshold Vₜₕ₀”. That is, as a constant value necessary for the explanation of the input voltage Vᵢₙ of the pulse generator pertaining to the first embodiment, the initial value of the inverter threshold Vₜₕ is defined as a reference value, because the first terms on the right sides in each of Eqs. (1) and (3) must be fixed values, respectively, as the first terms mean DC components, respectively. According to the pulse generator pertaining to the first embodiment, the no-load inverter-threshold Vₜₕ₀=f(V_{C0}) is used as the reference value, and the swing-center potential V_{th_c} represented in the first terms on the right sides in each of Eqs. (1) and (3) are represented by following Eq. (7a):

V_{th_c}=Vₜₕ₀−ΔV_{mod_H} (7a).

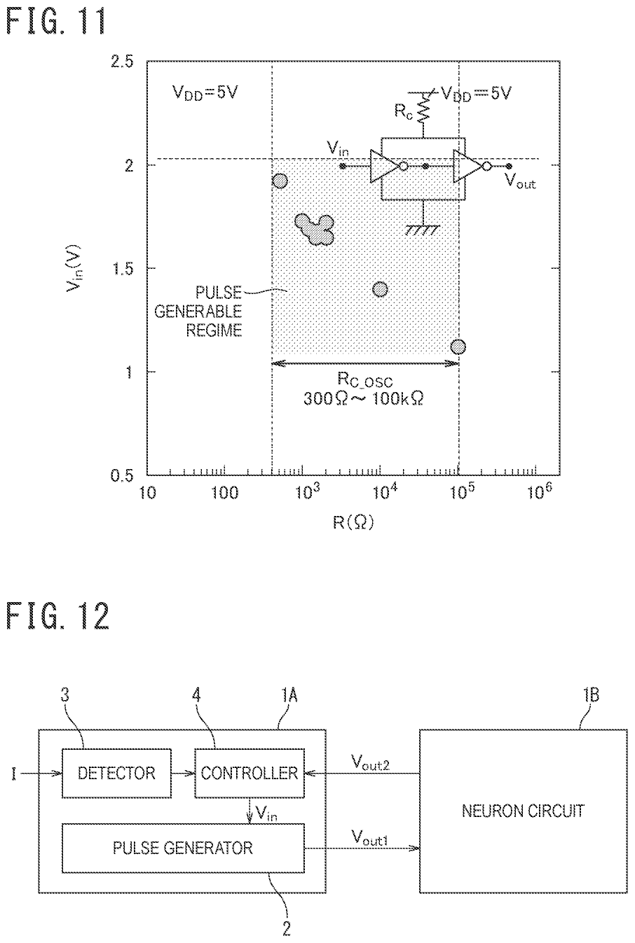

ΔV_{mod_H} on the right side in Eq. (7a) is “a voltage-adjustment parameter” that is experimentally determined, in order to adjust the values of the swing-center potentials V_{th_c} represented in the first terms on the right sides in each of Eqs. (1) and (3) to reasonable values with respect to the no-load inverter-threshold Vₜₕ₀. If the voltage-adjustment parameter is ΔV_{mod_H}=0, V_{th_c}=Vₜₕ₀ is established from Eq. (7a). However, adjustments based on experimental data are required, which will be explained later. The reason why “o” is appended to the end of the subscripts of the effective drive spans ΔVₜₕ₀ of the second terms on the right sides in each of Eqs. (1) and (3) lies in the definition in FIG. 8. The effective drive span ΔVₜₕ₀ is defined as a length of a bottom side of the triangle, setting the no-load inverter-threshold Vₜₕ₀ as a center of the bottom side, as can be understood from FIG. 8. The voltage-adjustment parameters ΔV_{mod_H} are the values depending on the resistance values of the resistive elements R_{C}, as can be understood from FIG. 11 described later.

ΔV_{mod_H}=η(R_{C}) (7b)

Then, the voltage-adjustment parameters ΔV_{mod_H} can be represented as a function η(R_{C}) of the resistance values of the resistive elements R_{C}, as represented by the Eq. (7b). If the resistance value of the resistive element R_{C} is determined by a method of the present Specification, the method will be described later, the values of the voltage-adjustment parameters ΔV_{mod_H} are elected as the fixed values, from Eq. (7b). Thus, the first terms on the right sides in each of Eqs. (1) and (3) become fixed values.

In addition, in the configuration of the pulse generator 10 pertaining to the first embodiment illustrated in FIG. 1, it is allowed that a waveform-observing unit (output observation circuit) for measuring variations with respect to the output voltages Vₒᵤₜ is installed on an output side of the output circuit 11. And furthermore, when a voltage-generator controller is further installed on an input side of the voltage source 12, data of the output voltages Vₒᵤₜ can be fed back to the voltage-generator controller from the waveform-observing unit. That is, it is allowed that by the feedback data from the waveform-observing unit, the voltage-generator controller can control the voltage source 12, and the voltage source 12 carries out a feedback control. In the feedback control, the values of the swing-center potential V_{th_c}, the effective drive span ΔV_{osc} and the additional wingspan ΔVₙₒₙ₋ₒₛ can be adjusted to optimal values, respectively, in view of the variations of the resistance values of the resistive element R_{C}. According to the mechanism of the pulse generator 10 pertaining to the first embodiment, the phases of the input and the output are not always required to be inverted, differently from a case of a ring oscillator. Also, as explained with regard to Eq. (12), a function Φ(t) may be periodic signals such as a saw-tooth wave or a rectangular wave, or alternatively, may be non-periodic signals. Thus, various waveforms generators, such as a sinusoidal wave generator, a saw-tooth wave generator, a rectangular wave generator and others, may be employed as the voltage source 12. Furthermore, the voltage-generator controller may control the voltage source 12 to provide the sinusoidal wave, the saw-tooth wave, the rectangular wave, or others, after controlling the voltage source 12 to select any one of various waveforms of the generating pulses, such as the sinusoidal wave, the saw-tooth wave, the rectangular wave, or others.

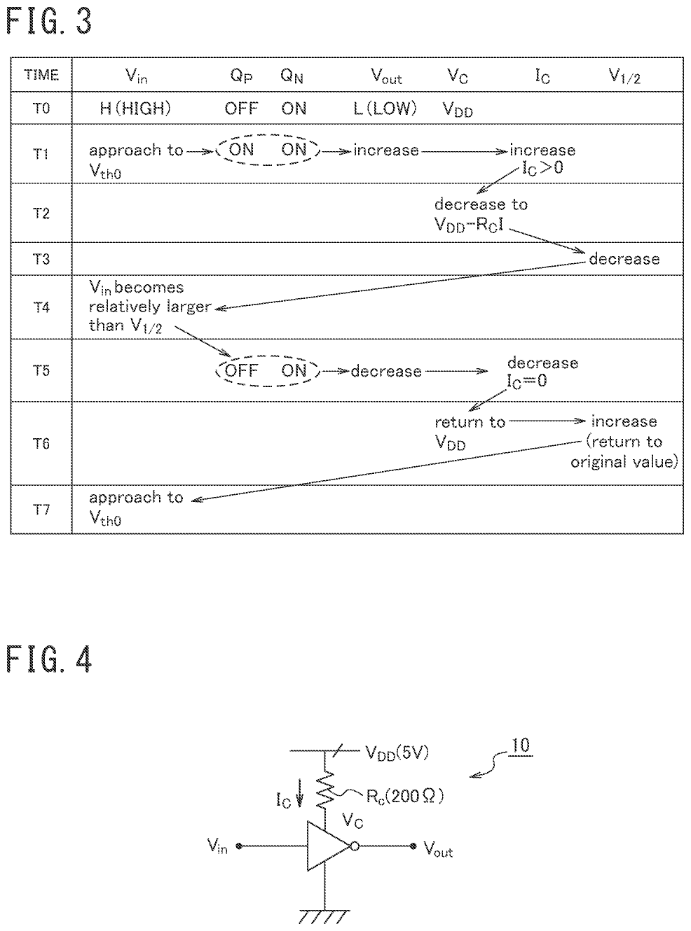

In FIG. 8, although the no-load inverter-threshold Vₜₕ₀, serving as the reference of the swing-center potential V_{th_c} in Eqs. (1) and (3), is defined as the voltage at which the vertical line, passing through the apex of the triangle delineated by the solid line, crosses the voltage axis in I-V characteristic diagram, the no-load inverter-threshold Vₜₕ₀ corresponds to a central value of voltages at which shoot-through currents flow in usual CMOS inverters having no resistive load. As explained already, the voltages in the range spanning the length of the bottom side in the triangle delineated by the solid line in FIG. 8 is the effective drive span ΔVₜₕ₀ of the pulse generator pertaining to the first embodiment. The additional wingspan ΔVₙₒₙ₋ₒₛ implementing a part of the amplitude of the AC component of the second terms on the right sides in Eqs. (1) and (3) is the total value of the widths of the voltage spans, each of which is expanded and defined by the width of ΔVₙₒₙ₋ₒₛ/2 in the shapes of wings on each of both sides of the bottom side in the triangle delineated by the solid line in FIG. 8. According to the pulse generator pertaining to the first embodiment, because the voltage V_{C0} of the original higher-potential side node V_{C} to which the shoot-through current does not flow is a fixed value (=V_{DD}), the no-load inverter-threshold Vₜₕ₀ is the fixed value. Therefore, the first terms on the right sides in each of Eqs. (1) and (3), based upon the no-load inverter-threshold Vₜₕ₀ as the reference, becomes the fixed values corresponding to the DC component. In the following, as the input voltage Vᵢₙ, the sinusoidal wave is assumed to be superimposed on the DC components prescribed by Eqs. (1) and (3). And, referring to a timing table illustrated in FIG. 3, the voltage source 12 will be explained such that the assumed input voltage Vᵢₙ is fed to the output circuit 11.

### Pulse Generation Principle

In the timing table illustrated in FIG. 3, an input voltage Vᵢₙ in which a sinusoidal wave, whose oscillation span is limited by an effective drive span ΔV_{osc}, is superimposed on the DC component prescribed by Eq. (3) is assumed to be supplied to the output circuit 11 by the voltage source 12. The uppermost row of the timing table illustrated in FIG. 3 indicates an initial state in which the spike-train signal is not generated, at a timing of time T0. At time T0, with regard to the voltage source 12, the input voltage Vᵢₙ prescribed by Eq. (3) is assumed to be located on “H (high)” level higher than the swing-center potential V_{th_c} and exhibit a gradually decreasing trend in a sinusoidal wave cos (ωt) of a frequency ω toward the swing-center potential V_{th_c}. At this time, the pMOS transistor Q_{P} is kept in cut-off state, and the nMOS transistor Q_{N} is also kept in conductive state. Thus, the output voltage Vₒᵤₜ of the resistor-connected complementary transistor-circuit illustrated in FIG. 2 becomes “L (Low)=0 V”. However, since the shoot-through current does not flow, the higher-potential side node V_{C} at the connection node between the resistive element R_{C} and the pMOS transistor Q_{P} is kept in the power-supply voltage V_{DD}.

Although the timing table illustrated in FIG. 3 exemplifies a case in which in the pulse generator pertaining to the first embodiment, the input voltage Vᵢₙ in the initial state (time T0) is located on the “H (high)” level higher than the swing-center potential V_{th_c}, a case may be assumed in which the input voltage Vᵢₙ is located on the “L” level lower than the swing-center potential V_{th_c} and exhibits a gradually increasing trend in the sinusoidal wave cos (ωt) of the second term on the right side in Eq. (3) toward the swing-center potential V_{th_c}. Next, at time T1, the voltage source 12 gradually decreases the input voltage Vᵢₙ toward the swing-center potential V_{th_c} from the voltage on the “H” level, in the sinusoidal wave of cos (ωt) represented at the second term on the right side.

When the input voltage Vᵢₙ is gradually decreased in the sinusoidal wave of cos (ωt) represented at the second term on the right side and becomes lower than the upper limit value (V_{th_c}+ΔV_{osc}/2) of the effective drive span ΔV_{osc} and is plunged toward the swing-center potential V_{th_c} at a speed slower than a time constant of the CMOS inverter, a voltage V_{GS} between gate and source is biased in such a way that the pMOS transistor Q_{P} is turned on, while conductive state of the nMOS transistor Q_{N} is kept. When a potential with respect to holes just under the gate electrode of the pMOS transistor Q_{P} begins to drop in such a way that the pMOS transistor Q_{P} transits to conductive state, a displacement current is generated which is caused by gate capacitance such as a capacitance C_{GS} between gate and source in the pMOS transistor Q_{P}. The displacement current induces a spike voltage capacitively generated in the pMOS transistor Q_{P} due to the instantaneous pseudo-short-circuit, the output voltage Vₒᵤₜ is sharply risen from “L=0 V” to a value close to the voltage V_{C0} of the original higher-potential side node V_{C}, which will be explained later with reference to FIG. 5A. Since the value of the spike voltage is slightly smaller than the power-supply voltage V_{DD}, the output voltage Vₒᵤₜ is not perfectly increased to the height of the power-supply voltage V_{DD}. Due to the variation of the potential just under the gate electrode of the pMOS transistor Q_{P}, when a channel begins to be formed just under the gate electrode of the pMOS transistor Q_{P}, the pMOS transistor Q_{P} enters a transient conductive state, and a conduction current begins to flow in a saturation region near a linear region of the pMOS transistor Q_{P}. That is, since both pMOS transistor Q_{P} and nMOS transistor Q_{N} turn into conductive state, a shoot-through current I_{C} (>0) as a DC current (conduction current) begins to flow through the CMOS inverter.

After the capacitive spike voltage is generated at time T1, the shoot-through current I_{C} begins to flow as the conduction current. Thus, at time T2, the potential of the higher-potential side node V_{C} is decreased from the power-supply voltage V_{DD}=V_{C0} to a value represented by following Eq. (8):

V_{C1}=V_{DD}−R_{C}I (8).

Here, R_{C} of Eq. (8) is the resistance value of the resistive element R_{C}, and I is a current value of the shoot-through current I_{C}, as a result that both of the pMOS transistor Q_{P} and the nMOS transistor Q_{N} turn into conductive state. As the potential of the higher-potential side node V_{C} is decreased from V_{C0} to V_{C1}, at time T3, the reference voltage necessary for the simultaneous-conductive state of the CMOS inverters is decreased from the original no-load inverter-threshold Vₜₕ₀ to an under-load inverter-threshold Vₜₕ=f (V_{C1})<Vₜₕ₀.

The current value I of the shoot-through current I_{C} in Eq. (8) depends on a current I_{DS_nMOS} between drain and source in the nMOS transistor Q_{N} and a current I_{DS_pMOS} between drain and source electrode of the pMOS transistor Q_{P}. The current I_{DS_nMOS} between drain and source in the nMOS transistor Q_{N} is represented by following Eq. (9a), and the current I_{DS_pMOS} between drain and source electrode of the pMOS transistor Q_{P} is represented by following Eq. (9b):

I_{DS_nMOS}=(½)βₙ(Vᵢₙ−V_{th_n})² (9a)

I_{DS_pMOS}=(½)βₚ(Vᵢₙ−V_{th_p}|)² (9b)

The frequency ω of the sinusoidal wave of cos (ωt) represented at the second term on the right side in Eq. (3) is selected as a frequency that is sufficiently slower than each of the turn-on time and the turn-off time of the pMOS transistor Q_{P}. And, at time T4, when the change of the input voltage Vᵢₙ becomes faster than the variation of the frequency ω, and the reference voltage necessary for the simultaneous-conductive state of the CMOS inverters has decreased to an under-load inverter-threshold Vₜₕ₁=f(V_{C1}), the input voltage Vᵢₙ becomes relatively larger than the under-load inverter-threshold Vₜₕ₁, and therefore, the input voltage Vᵢₙ becomes a potential at a level being deviated from the under-load conductive-spans ΔVₜₕ₁, which are defined on both sides of the under-load inverter-threshold Vₜₕ₁ at a center.

Vᵢₙ>Vₜₕ₁+(½)ΔVₜₕ₁ (10)

As represented in Eq. (10), when the input voltage Vᵢₙ becomes relatively larger than the voltage of the upper edge of the under-load conductive-span ΔVₜₕ₁, whose reference is the under-load inverter-threshold Vₜₕ₁, the pMOS transistor Q_{P} transits to cut-off state, and the nMOS transistor Q_{N} is kept in conductive state. When the pMOS transistor Q_{P} enters cut-off state, charges begin to be accumulated in the gate capacitance such as the capacitance C_{GS} between gate and source in the pMOS transistor Q_{P}. Thus, at time T5, the output voltage Vₒᵤₜ will decrease toward “L≈0 V”, and the shoot-through current I_{C} also decreases toward zero. Also, since the shoot-through current I_{C} does not flow as the conduction current, the higher-potential side node V_{C} is recovered from V_{C1}=(V_{DD}−R_{C}I) to the power-supply voltage V_{DD}=V_{C0}. Since the shoot-through current I_{C} does not flow, the inverter threshold Vₜₕ necessary for the simultaneous-conductive state of the CMOS inverters is increased at time T6, and recovered from the under-load inverter-threshold Vₜₕ₁ at time T4 to the original no-load inverter-threshold (initial value) Vₜₕ₀=f(V_{C0}).

At time T7 at which the inverter threshold Vₜₕ necessary for the simultaneous-conductive state is recovered to the initial value Vₜₕ₀, the input voltage Vᵢₙ again approaches the swing-center potential V_{th_c} that is set with the original no-load inverter-threshold Vₜₕ₀=f(V_{C0}).

Vᵢₙ≤V_{th_c}+(½)ΔVₜₕ₀ (11)

When Eq. (11) is hold, the input voltage Vᵢₙ becomes the state equal to the time T1. That is, as long as the input voltage Vᵢₙ, which swings according to the sinusoidal wave of cos (ωt) prescribed by Eq. (3), alters at a speed slower than a repetitive frequency of the spike-train signal, or slower than the time constant of the CMOS inverter, the states of the timings T1 to T7 are repeated, and therefore, the spike-train signals are delivered from the output circuit 11.

When the reduction of the input voltage Vᵢₙ, caused by the sinusoidal wave of cos (ωt) at the second term on the right side in Eq. (3), brings to levels belonging to the range between the upper limit value (V_{th_c}+ΔV_{osc}/2) and the lower limit value (V_{th_c}−ΔV_{osc}/2) of the effective drive span ΔV_{osc} with the swing-center potential V_{th_c} at a center, the states of the timings T1 to T7 are repeated, and therefore, the output voltage Vₒᵤₜ fluctuates. When the reduction of the input voltage Vᵢₙ, caused by the sinusoidal wave of cos (ωt) at the second term on the right side in Eq. (3), brings to levels exceeding the lower limit value (V_{th_c}−ΔV_{osc}/2) of the effective drive span ΔVₙₒₙ₋ₒₛ, and is further decreased to a level in a range at the additional wingspan ΔVₙₒₙ₋ₒₛ, the nMOS transistor Q_{N} transits to cut-off state, and the spike-train signal is not generated, and the signal of “H” level is delivered as the output signal from the output circuit 11.

As more time elapses, after the variation of the sinusoidal wave of cos (ωt) at the second term on the right side in Eq. (3) has passed through the minimum value, the input voltage Vᵢₙ begins to gradually re-rise obeying the sinusoidal wave of cos (ωt) to the swing-center potential V_{th_c} from the “L” side. When the variation of the input voltage Vᵢₙ is increased to a value exceeding the lower limit value (V_{th_c}−ΔV_{osc}/2) of the effective drive span ΔV_{osc}, the nMOS transistor Q_{N} transits to conductive state. Accordingly, the input voltage Vᵢₙ arrives at the levels in which both of the pMOS transistor Q_{P} and the nMOS transistor Q_{N} can be turned on. When the input voltage Vᵢₙ is slowly increased in the effective drive span ΔV_{osc}, the operation states similar to the timings T1 to T7 are repeated, similarly to the timing table illustrated in FIG. 3. Since the operation states similar to the timings T1 to T7 are repeated, the output voltage Vₒᵤₜ is fluctuated, and the spike-train signals are delivered from the output circuit 11. As more time elapses, the sinusoidal wave of cos (ωt) at the second term on the right side in Eq. (3) becomes large. Then, when the input voltage Vᵢₙ is increased to the “H” level up to a value exceeding the upper limit value (V_{th_c}+ΔV_{osc}/2) of the effective drive span ΔV_{osc}, the spike-train signal is not generated, and the output signal from the output circuit 11 remains at “L≈0 V”.

On the basis of the pulse generation principle exemplified in the timing table illustrated in FIG. 3, in order to verify the operations in which the pulse generator represented in FIGS. 1 and 2 generates the spike-train signal, the inventors of the present invention have trial manufactured the output circuit 11 of the resistor-connected complementary transistor-circuit as illustrated in FIG. 4. Although FIG. 5B is a view in which a time axis in FIG. 5A is extended, FIGS. 5A and 5B illustrate measured waveforms provided by the resistor-connected complementary transistor-circuit illustrated in FIG. 4. The power-supply voltage of the resistor-connected complementary transistor-circuit illustrated in FIG. 4 is assigned to V_{DD}=5 volts, and the resistance value of the resistive element R_{C} is set to be 200 ohms. Also, for the input voltage Vᵢₙ when the spike-train signal is generated, 2.2 volts is applied as the swing-center potential V_{th_c} necessary for the simultaneous-conductive state. The value of V_{th_c}=2.2 volts is low by 0.3 volt, as compared with the central value (V_{DD}/2=2.5 volts) of the voltage between the higher-potential power-supply V_{DD} and the lower-potential power-supply (ground potential=0 volt).

If the variation of the sinusoidal wave of cos (ωt) at the second term on the right side in Eq. (3) provides levels belongs to the range between the upper limit value (V_{th_c}+ΔV_{osc}/2) and the lower limit value (V_{th_c}−ΔV_{osc}/2) of the effective drive span ΔV_{osc}, the spike-train signals can be delivered. Thus, FIG. 5A intermittently illustrates quadruple groups of spike trains in all. That is, FIG. 5A illustrates a way the spike-train signals can be generated when the variation of the amplitude of the sinusoidal wave of cos (ωt) provides levels belongs to the range between the upper limit value (V_{th_c}+ΔV_{osc}/2) and the lower limit value (V_{th_c}−ΔV_{osc}/2) of the effective drive span ΔV_{osc}. And FIG. 5A further illustrates a way the spike-train signal is not generated, when the amplitude of the sinusoidal wave of cos (ωt) is increased up to the levels exceeding the upper limit value (V_{th_c}+ΔV_{osc}/2) of the effective drive span ΔV_{osc} and increased. One group of spike trains on the left end side in FIG. 5A indicates a case in which the input voltage Vᵢₙ prescribed by Eq. (3) is increased with the elapse of time, from a small amplitude on the “L” side and increased up to a value exceeding (V_{th_c}−ΔV_{osc}/2) and plunged into the effective drive span ΔV_{osc}. At the moment of starting the operation in which both of the pMOS transistor Q_{P} and the nMOS transistor Q_{N} try to turn into conductive states, due to the generation of the displacement current caused by the gate capacitance of the pMOS transistor Q_{P}, the output voltage Vₒᵤₜ induces the spike voltages that are sharply risen up to the values close to the voltage V_{C0}=V_{DD} of the original higher-potential side node V_{C}.

As can be understood from FIG. 5A, a value of the spike voltage is about 4.2 volts slightly smaller than the power-supply voltage V_{DD}=5 volts. Although the potential of holes just under the gate electrode of the pMOS transistor Q_{P} begins to be dropped, the pMOS transistor Q_{P} does not enters the perfect conductive state, and an on-resistance R_{ON_P} of the pMOS transistor Q_{P} is relatively high. When the potential of holes just under the gate electrode of the pMOS transistor Q_{P} begins to drop, the potential of electrons just under the gate electrode of the nMOS transistor Q_{N} rises and begins to move in a direction in which the potential is shifted from a saturation region to a linear region side. And, since the shoot-through current I_{C} is made to flow ascribable to the condition that both the pMOS transistor Q_{P} and the nMOS transistor Q_{N} enter an intermediate (insufficient) conductive state, the potential of the higher-potential side node V_{C} is decreased, which causes the pMOS transistor Q_{P} to enter cut-off state. Even if the pMOS transistor Q_{P} enters cut-off state, as illustrated in FIG. 5A, the output voltage Vₒᵤₜ does not become perfect zero-volt and has decreased to “L≈0 V” close to zero-volt. This is because at a stage at which the pMOS transistor Q_{P} enters cut-off state, the nMOS transistor Q_{N} is still kept in the transient conductive state close to the boundary between the linear region and the saturation region, and even an on-resistance R_{ON_N} of the nMOS transistor Q_{N} still is kept in the relatively high state. In light of the condition of the later-described Eq. (20), in the case of ßₙ>ßₚ prescribed by Eqs. (9a) and (9b), it is difficult for the current in the perfect saturation region to flow through the nMOS transistor Q_{N}, and even the on-resistance R_{ON_N} is relatively high. As a result, a voltage drop caused by the on-resistance R_{ON_N} of the nMOS transistor Q_{N} is generated at a non-negligible magnitude. Thus, the output voltage Vₒᵤₜ is not reached to a perfect zero-volt level. When the pMOS transistor Q_{P} enters cut-off state, the potential of the higher-potential side node V_{C} is recovered, which starts an operation for the pMOS transistor Q_{P} to try to enter again the transient conductive state. Such operations for alternating the conductive states and the cut-off states of the pMOS transistor Q_{P} generate the spike pulses, and the spike-train signals are delivered as the output voltage Vₒᵤₜ.

In this way, operations are repeated in which, when the input voltage Vᵢₙ illustrated in FIG. 3 is increased up to the levels exceeding the (V_{th_c}−ΔV_{osc}/2) in the time period of the left end in FIG. 5A and plunged into the effective drive span ΔV_{osc} at the speed slower than the time constant of the CMOS inverter, both pMOS transistor Q_{P} and nMOS transistor Q_{N} turn into conductive states. An operation in which the variation of the input voltage Vᵢₙ is slower than the time constant of the CMOS inverter and both pMOS transistor Q_{P} and nMOS transistor Q_{N} try to enter the intermediate (partial) conductive state is repeated, thereby generating the spike-train signals. As can be understand from FIG. 5A, the potential at the higher-potential side node V_{C} is also oscillated together with the voltage oscillation of the output voltage Vₒᵤₜ as illustrated at the left end of FIG. 5A. Also, even the shoot-through current I_{C} is oscillated together with the voltage oscillation of the output voltage Vₒᵤₜ as illustrated at the left end of FIG. 5A.

With the further elapse of time, the amplitude of the sinusoidal wave of cos (ωt) at the second term on the right side in Eq. (3) becomes large and is increased to the levels exceeding (V_{th_c}+ΔV_{osc}/2), and therefore, the levels of the sinusoidal wave of cos (ωt) are deviated from the effective drive span ΔV_{osc}, then the generation of the spike-train signals is stopped. When the amplitude of the sinusoidal wave of cos (ωt) is increased to the “H” level exceeding (V_{th_c}+ΔV_{osc}/2), even in a case that the potential of the higher-potential side node V_{C} has decreased to V_{C1} by the shoot-through current I_{C}, the pMOS transistor Q_{P} is kept in cut-off state because the input voltage Vᵢₙ deviated from the effective drive span ΔV_{osc} of the CMOS inverter. If the pMOS transistor Q_{P} is kept in cut-off state, the accumulation of the charges in the gate capacitance of the pMOS transistor Q_{P} is kept. That is, focusing to the spike-train signals in the leftmost time period illustrated in FIG. 5A, when the pMOS transistor Q_{P} enters cut-off state at the completion timing at the right edge in the leftmost time period (oscillation period), the pMOS transistor Q_{P} is kept in cut-off state, and the nMOS transistor Q_{N} is kept in conductive state after the right edge completion timing. That is, as illustrated in FIG. 5A, in the time period after the completion of the generation of one group (cluster) of the leftmost spike trains, the output voltage Vₒᵤₜ from the output circuit 11 is still “L≈0 V”.

As can be understood from Eq. (3), when the sinusoidal wave of cos (ωt) at the second term on the right side in Eq. (3) continues to be increased with the elapse of time, the input voltage Vᵢₙ begins to decrease again and slowly after passing through the maximum value. When the input voltage Vᵢₙ has decreased to a value smaller than (V_{th_c}+ΔV_{osc}/2), the input voltage Vᵢₙ is plunged into the effective drive span ΔV_{osc} in the second oscillation period from the left in FIG. 5A. Both pMOS transistor Q_{P} and nMOS transistor Q_{N} turn into conductive state, in the effective drive span ΔV_{osc} in the second oscillation period from the left in FIG. 5A. And, a second cluster (one group) of spike trains in the second oscillation period from the left is generated because an operation for the pMOS transistor Q_{P} to repeat conductive state and cut-off state is repeated in the second oscillation period from the left in FIG. 5A. The second cluster of spike trains in the second oscillation period from the left continues to be generated in the time period in which the peak value of the input voltage Vᵢₙ belongs to the second effective drive span ΔV_{osc} in the second oscillation period from the left in FIG. 5A. As illustrated in FIG. 5A, even the potential at the higher-potential side node V_{C} is oscillated together with the voltage oscillation of the output voltage Vₒᵤₜ in the second oscillation period from the left, which is located at the right of the timing of the output voltage Vₒᵤₜ=L in FIG. 5A. Also, the shoot-through current I_{C} is oscillated together with the voltage oscillation of the output voltage Vₒᵤₜ in the second oscillation period from the left in FIG. 5A.

With the elapse of time, when the reduction of the sinusoidal wave of cos (ωt) at the second term on the right side in Eq. (3) is proceeded and the input voltage Vᵢₙ is decreased beyond (V_{th_c}−ΔV_{osc}/2), the input voltage Vᵢₙ is deviated from the effective drive span ΔVᵢₙ When the input voltage Vᵢₙ has decreased to a potential deviated from the effective drive span ΔV_{osc}, the nMOS transistor Q_{N} transits to cut-off state. That is, at the timing at which the potential of the higher-potential side node V_{C} is recovered to the voltage V_{C0} of the original higher-potential side node V_{C}, after the potential of the higher-potential side node V_{C} has decreased to V_{C1} by the shoot-through current I_{C}, the nMOS transistor Q_{N} enters cut-off state because the input voltage Vᵢₙ is deviated from the effective drive span ΔV_{osc}. When the pMOS transistor Q_{P} is kept in conductive state and the nMOS transistor Q_{N} is kept in cut-off state, the potential of the output voltage Vₒᵤₜ is kept at a value close to the voltage V_{C0}=V_{DD} of the original higher-potential side node V_{C}. In this way, if the nMOS transistor Q_{N} is kept in cut-off state, the spike-train signal is not delivered, and the signal of the “H” level is delivered as the output signal from the output circuit 11. That is, in the time period after the completion of the generation of the second cluster of spike trains in the second oscillation period from the left in FIG. 5A, although the output voltage Vₒᵤₜ from the output circuit 11 is close to the power-supply voltage V_{DD}, the output voltage Vₒᵤₜ is located at the “H” level smaller than the power-supply voltage V_{DD}.

With the further elapse of time, the amplitude of the sinusoidal wave of cos (ωt) at the second term on the right side in Eq. (3) becomes the minimum value. After that, the amplitude begins to be slowly increased from the minimum value. When the amplitude of the sinusoidal wave of cos (ωt) at the second term on the right side in Eq. (3) is gradually increased from the minimum value and exceeds (V_{th_c}−ΔV_{osc}/2), the input voltage Vᵢₙ is plunged into the effective drive span ΔV_{osc} in the third oscillation period from the left in FIG. 5A. When the variation of the input voltage Vᵢₙ is increased to a value at which the input voltage Vᵢₙ is plunged into the effective drive span ΔV_{osc}, both pMOS transistor Q_{P} and nMOS transistor Q_{N} turn into conductive state. And, in the third oscillation period from the left, an oscillation in which an alternating operation for the pMOS transistor Q_{P} to repeat conductive state and cut-off state is repeated is generated, thereby generating a third cluster of spike trains in the third oscillation period from the left in FIG. 5A. As illustrated in FIG. 5A, the potential at the higher-potential side node V_{C} is oscillated together with the voltage oscillation of the output voltage Vₒᵤₜ in the third oscillation period from the left in FIG. 5A. Also, even the shoot-through current I_{C} is oscillated together with the voltage oscillation of the output voltage Vₒᵤₜ in the third oscillation period from the left in FIG. 5A.

With the further elapse of time, when the sinusoidal wave of cos (ωt) at the second term on the right side in Eq. (3) becomes large and the input voltage Vᵢₙ is increased to the levels exceeding (V_{th_c}+ΔV_{osc}/2) and deviated from the effective drive span ΔVᵢₙ the generation of the spike-train signals is stopped. That is, in association with the increase of the amplitude of the sinusoidal wave of cos (ωt), when the input voltage Vᵢₙ is increased to the “H” level exceeding (V_{th_c}+ΔV_{osc}/2), the input voltage Vᵢₙ is deviated from the effective drive span ΔV_{osc}. Thus, the pMOS transistor Q_{P} is kept in cut-off state. That is, when the pMOS transistor Q_{P} enters cut-off state at the timing at which it is located at the right edge of the spike-train signal in the third oscillation period from the left in FIG. 5A, after the third oscillation period, the pMOS transistor Q_{P} is kept in cut-off state, and the nMOS transistor Q_{N} is kept in conductive state. That is, at the final timing of the third spike-train signal in the third oscillation period from the left in FIG. 5A, when the input voltage Vᵢₙ is increased to the “H” level exceeding (V_{th_c}+ΔV_{osc}/2), the pMOS transistor Q_{P} is kept in cut-off state, and the nMOS transistor Q_{N} is kept in conductive state. That is, as illustrated in FIG. 5A, in the time period after the completion of the generation of the third cluster of the spike trains in the third oscillation period from the left in FIG. 5A, the output signal from the output circuit 11 is still “L≈0 V”.

As represented by Eq. (3), the input voltage Vᵢₙ continues to be increased in association with the variation of the sinusoidal wave of cos (ωt) at the second term on the right side, and after passing through the maximum value, the input voltage Vᵢₙ begins to decrease again and slowly. When the input voltage Vᵢₙ has decreased to the value smaller than (V_{th_c}+ΔV_{osc}/2), the input voltage Vᵢₙ is plunged into the effective drive span ΔV_{osc} in the fourth oscillation period from the left in FIG. 5A. As long as the input voltage Vᵢₙ belongs to a level in the effective drive span ΔV_{osc} and the variation of the input voltage Vᵢₙ is slower than the time constant of the CMOS inverter, the operation for both of the pMOS transistor Q_{P} and the nMOS transistor Q_{N} to try to be turned on is repeated, thereby generating the spike-train signals. As long as the variation of the input voltage Vᵢₙ prescribed by Eq. (3) belongs to the level in the effective drive span ΔV_{osc} in the fourth oscillation period from the left in FIG. 5A, it is a time period in which a fourth (namely, rightmost) cluster of the spike trains in the fourth oscillation period from the left continues to be generated. As illustrated in FIG. 5A, the potential at the higher-potential side node V_{C} is oscillated together with the voltage oscillation of the output voltage Vₒᵤₜ in the fourth oscillation period from the left in FIG. 5A. Also, even the shoot-through current I_{C} is oscillated together with the voltage oscillation of the output voltage Vₒᵤₜ in the fourth oscillation period from the left in FIG. 5A.

With the further elapse of time, when the reduction of the sinusoidal wave of cos (ωt) at the second term on the right side in Eq. (3) is proceeded and the potential is decreased beyond (V_{th_c}−ΔV_{osc}/2), the potential of the input voltage Vᵢₙ is deviated from the effective drive span ΔV_{osc}. When the input voltage Vᵢₙ has decreased to the potential deviated from the effective drive span ΔVᵢₙ the nMOS transistor Q_{N} transits to cut-off state and kept in cut-off state. Due to the deviation from the effective drive span ΔV_{osc} of the CMOS inverter, the nMOS transistor Q_{N} is kept in cut-off state. However, since the pMOS transistor Q_{P} is kept in conductive state, the potential of the output voltage Vₒᵤₜ is kept at a value close to the voltage V_{C0}=V_{DD} of the original higher-potential side node V_{C}. In the time period in which the pMOS transistor Q_{P} is kept in conductive state and the nMOS transistor Q_{N} is kept in cut-off state, the spike-train signal is not delivered, and the signal of the “H” level is delivered as the output signal from the output circuit 11. That is, in the time period after the completion of the generation of the fourth cluster of the spike trains in the fourth oscillation period from the left in FIG. 5A, the output signal from the output circuit 11 is at the “H” level, as illustrated at the right-hand side in FIG. 5A.

The pulse generator represented in FIGS. 1 and 2 can be considered to have an AD conversion function of pulse width modulation (PWM), which converts analog values of the swinging input voltages (input values) Vᵢₙ, on which the sinusoidal wave of cos (ωt) is superimposed, into digital values as pike-shaped pulses, although minute variations of the input voltage Vᵢₙ cannot be read from the diagram illustrated in FIG. 5A. FIG. 5B illustrates the fourth cluster of the spike trains in the fourth oscillation period from the left in FIG. 5A in which the time axis is extended, and generation of nonuple spike trains is demonstrated between 4.4 milliseconds and 6.1 milliseconds.

FIGS. 5A and 5B illustrate that spontaneous spike-train signals are generated near 2.2 volts of the input voltage Vᵢₙ. In the illustration in FIG. 5B in which the time axis is extended, “fluctuation” is illustrated in which the slight variation of the input voltage Vᵢₙ leads to the variations of pulse widths of spike-shaped pulses and pulse intervals, and pulse widths on the trailing side of the pulse trains are extended. That is, FIG. 5A illustrates macro “fluctuation” in which cluster (one group) of spike-train signals are generated intermittently and periodically, similarly to the AD conversion function of PWM scheme. On the other hand, FIG. 5B illustrates the generation of micro “fluctuation” in which the slight reduction of the input voltage Vᵢₙ causes the increase of the pulse width of the spike-shaped pulses. Micro “fluctuation” can be also generated in the firing timings of the spike-shaped pulses by the slight variation of the input voltage Vᵢₙ, although the minute changes of the firing timings may be difficult to understand in FIG. 5B. That is, since gain is high near the inverter threshold Vₜₕ, the generations of the spike-shaped pulses are very sensitive to the fluctuations in the input potentials, and the pulse-firing timings are accordingly fluctuated. However, the fluctuations are not perfectly random fluctuations, and the variations of the pulse widths, pulse intervals and pulse-firing timings of the spike-shaped pulses can be somewhat controlled in a specific limited latitude, because the fluctuations are ascribable to the potentials of the input voltages Vᵢₙ.

That is, according to the pulse generator pertaining to the first embodiment, by slightly swinging the values of the input voltages Vᵢₙ entered to the output circuit 11 to values near the swing-center potential V_{th_c} of the resistor-connected complementary transistor-circuit, the pulse widths and pulse intervals, which are delivered from the output circuit 11, can be controlled as “the fluctuating signal controlled within a desirable latitude”. For example, the micro signals to be superimposed on the input voltage Vᵢₙ fed from the voltage source 12 are not limited to the sinusoidal waves of cos (ωt) exemplified in Eq. (3) and may be a saw-tooth wave, a rectangular wave, and others. More generally, by using a function Φ(t) that varies depending on time t, which includes the saw-tooth wave, the rectangular wave, and others, Eq. (3) can be represented by following Eq. (12):

Vᵢₙ=V_{th_c}+(½)(ΔV_{osc}+ΔVₙₒₙ₋ₒₛ)Φ(t) (12)

That is, the function Φ(t) may be a periodically-varying signal or a non-periodically-varying signal. For example, as described already, in the case that the DC voltage is supplied from the voltage source 12 built in the pulse generator 10 in FIG. 1, without using the voltage source 12 as a constant voltage supply of a higher precision, even if the input voltage Vᵢₙ on which minute ripple components are superimposed is designed to be delivered, the output circuit 11 can provide “a fluctuating signal” in which the fluctuations of the pulse widths, the pulse intervals, the pulse-firing timings, and others are controlled in a specific limited latitude. Even in a case that thermal noise is superimposed, since there is a limit to the wave height value (maximum voltage) of the thermal noise, it is possible to generate “the fluctuating signal controlled in a specific limited latitude”. Similarly, irregular signal waveforms such as thermal noise may be superimposed on a regular signal such as the sinusoidal wave, the saw-tooth wave, the rectangular wave, and others as the function Φ(t) represented at the second term on the right side in Eq. (12).

### Pulse Generation Condition

As the pulse generation conditions of the output circuit 11 in the pulse generator pertaining to the first embodiment illustrated in FIG. 2, there are the following two requirements:

### First Requirement

A first requirement is a capability of the inflow of the shoot-through current I_{C}. That is, the first requirement needs a presence of an input voltage Vᵢₙ for enabling the pMOS transistor Q_{P} and the nMOS transistor Q_{N}, which implement the resistor-connected complementary transistor-circuit, to enter into a simultaneous-conductive state (ΔI_{C}>0), as represented by solid line in FIG. 8. And, by the operation for driving the pMOS transistor Q_{P} and the nMOS transistor Q_{N} transistors into the simultaneous-conductive state, the shoot-through current I_{C} is transiently increased by ΔI_{C} as the peak value. From an I_{C} curve illustrated in FIG. 8, it is possible to get an information of a gate threshold V_{th_p} of the pMOS transistor Q_{P} and an information of a gate threshold V_{th_n} of the nMOS transistor Q_{N}.

### Second Requirement

A second requirement requires a behavior such that the potential at the higher-potential side node V_{C} in the circuit topology illustrated in FIG. 2 shall decrease by the generation of the shoot-through current I_{C} flowing through the resistive element R_{C}, and the inverter threshold Vₜₕ necessary for the simultaneous-conductive state of the CMOS inverters shall be decreased.

In light of the first and second requirements, the conditions for determining the resistance values of the resistive elements R_{C} can be written as followings.

R_{C}I_{C0}<V_{DD}+V_{th_p}−V_{th_n} (13)

R_{C}(A′ΔI_{C}+I_{C0})>V_{DD}+V_{th_p}−V_{th_n} (14)

A′=Aβₚ^{1/2}/(βₙ^{1/2}+βₚ^{1/2}) (15)

However, I_{C0} written on the left sides in Eqs. (13) and (14) is the value of unintentional (non-intended) shoot-through current I_{C} associated with sub-threshold currents in an initial state (Vᵢₙ=“H” or “L”) and leakage currents (leakage current between V_{DD} and V_{SS}), and I_{C0} is mainly composed of DC components. In the unintentional shoot-through current I_{C0}, components caused by non-ideal factors such as manufacturing processes and others are main, and the unintentional shoot-through current I_{C0} contains variability and dispersion. Coefficient A on the right side defining a resistance-value setting-coefficient A′ in Eq. (15) corresponds to “the EDSS coefficient”, which will be explained in Eq. (19a). The effective drive span ΔV_{osc} to achieve the voltage-oscillation of the higher-potential side node V_{C} can be determined in the span of the simultaneous-conduction regime ΔVₜₕ₀ with the EDSS coefficient A, by making the CMOS inverter to operate in the simultaneous-conductive state effectively and sufficiently, and furthermore, by flowing the necessary shoot-through current. The EDSS coefficient A=1 corresponds to a condition that the pMOS transistor Q_{P} is strictly turned off due to the variation ΔVₜₕ₀ of the inverter threshold Vₜₕ₀ necessary for the simultaneous-conductive state. Experimentally, in the range of the EDSS coefficient A≈7 to 15, for example, at A≈10, the spike-shaped pulses ares generated as illustrated in FIGS. 5A and 5B.

Also, the resistance-value setting-coefficient A′ prescribed by Eqs. (14) and (15) is a value that is experimentally calculated from ßₙ and ßₚ with the EDSS coefficient A as a parameter. Usually, the resistance-value setting-coefficients are values of A′≈5 to 20, preferably, A′≈8 to 15. For example, the resistance-value setting-coefficient can be set as A′≈10. As explained already in Eq. (12), ßₚ is the coefficient for determining drain currents in saturation region of the pMOS transistor Q_{P}, and ßₙ is the coefficient for determining drain currents in saturation region of the nMOS transistor Q_{N}. Also, experimentally, the range of the resistive elements R_{C} that enables the pulses to be generated by the pulse generator pertaining to the first embodiment is a region slightly wider than a scope determined by inequality expressions in Eqs. (13) and (14). Moreover, the unintentional shoot-through current I_{C0} has the variations due to the non-ideal factors. Thus, the upper limits of the resistance values of the resistive elements R_{C} tend to be fluctuated.

Eq. (13) can be rewritten as in Eq. (16), by using the relation of the following Eq. (17).

V_{th_n}<V_{C0}+V_{th_p} (16)

V_{C0} prescribed by Eq. (16) is the potential at the higher-potential side node V_{C} in the initial state in the circuit topology illustrated in FIG. 2, and can be represented, similarly to the already-explained Eq. (8), as follows:

V_{C0}=V_{DD}−R_{C}I_{C0} (17).

Here, R_{C} of Eq. (17) is the resistance value of the resistive element R_{C}.

In light of Eq. (16), in a case of a situation that the following Eq. (18) holds, the pMOS transistor Q_{P} and the nMOS transistor Q_{N} cannot be turned on simultaneously, for any input value (input voltage Vᵢₙ). Thus, the shoot-through current cannot flow through the resistor-connected complementary transistor-circuit.

V_{th_n}>V_{C0}+V_{th_p} (18)

In addition, when the transient shoot-through current I_{C} begins to flow, a potential at the higher-potential side node V_{C} is decreased, which leads to a possibility the potential at that the higher-potential side node V_{C} cannot comply with Eq. (16). However, even in the foregoing case, because the reduction of the potential at the higher-potential side node V_{C} causes one of the pMOS transistor Q_{P} and the nMOS transistor Q_{N} to transit to cut-off state, the shoot-through current I_{C} is stopped, and the potential at the higher-potential side node V_{C} is again increased. Hence, the potential at the higher-potential side node V_{C} is spontaneously returned to comply with Eq. (16).

The second requirement can be represented by following Eqs. (19a) to (19c).

ΔV_{osc}>(V_{C}+V_{th_p}−Vₜₕ₋ₙ)/A (19a)

V_{C}=V_{DD}−R_{C}I_{C} (19b)

I_{C}=I_{C0}+ΔI_{C} (19c)

As explained in Eq. (15), “A” of a denominator on a right side in Eq. (19a) is the EDSS coefficient. The EDSS coefficient defines the effective drive span ΔV_{osc} required to make the CMOS inverters enter the effective simultaneous-conductive state, by which the valid shoot-through current can flow. Furthermore, the EDSS coefficient defines the effective drive span ΔV_{osc} required to achieve the voltage-oscillation of the higher-potential side node V_{C} in the span of the simultaneous-conduction regime ΔVₜₕ₀. Experimentally, the EDSS coefficient A is approximately equal to about seven to fifteen, and typically, A is approximately equal to about ten.

That is, if the input voltage Vᵢₙ is set to the voltage within the effective drive span ΔV_{osc} with the swing-center potential V_{th_c} of the CMOS inverter at a center, the pMOS transistor Q_{P} and the nMOS transistor Q_{N} enter the simultaneous-conductive state that is effectively available, and the transient shoot-through current I_{C} is generated. At this time, since the voltage drop in the resistive element R_{C} causes the potential at the higher-potential side node V_{C} to be decreased, the inverter threshold Vₜₕ necessary for the simultaneous-conductive state of the CMOS inverters is decreased, and the input voltage Vᵢₙ is relatively increased with respect to the swing-center potential V_{th_c}. Because the simultaneous-conduction regime ΔVₜₕ₀, which is the amount of change in the inverter threshold Vₜₕ₀, is finite as illustrated by the length of the bottom side in the triangle exhibited in FIG. 8, the pMOS transistor Q_{P} transits from conductive state to cut-off state, and the shoot-through current I_{C} is spontaneously decreased.

In principle, as prescribed by Eq. (3), in the initial state, the swing-center potential V_{th_c} of the input voltage Vᵢₙ does not have to exactly coincide with the inverter threshold Vₜₕ₀ of the CMOS inverter, and allowable to have values close to the inverter threshold Vₜₕ₀. In a state when the shoot-through current is flowing, the drain currents of the pMOS transistor Q_{P} and the nMOS transistor Q_{N} are required to coincide with each other. Thus, the condition of the following Eq. (20) is required.

I_{DS_nMOS}=I_{DS_pMOS} (20)

The drain current I_{DS-nMOS} of the nMOS transistor Q_{N} prescribed by Eq. (20) is given by Eq. (9a) as explained already. Also, the drain current I_{DS_pMOS} of the pMOS transistor Q_{P} is obtained by Eq. (9b).

By substituting the right side of each of Eq.s (9a) and (9b) into Eq. (20), it is possible to derive the following Eqs. (21) and (22).

$${V}_{th} = \frac{\sqrt{{β}_{n}} \cdot {V}_{th . n} + \sqrt{{β}_{p}} \cdot ( {V}_{C} + {V}_{th\_p}}{\sqrt{{β}_{n}} + \sqrt{{β}_{p}}} \qquad ( 21 )$$

$$Δ {I}_{C} = \frac{1}{2} \frac{{β}_{n} {β}_{p}}{{β}_{n} + {β}_{p} + 2 \sqrt{{β}_{n} {β}_{p}}} {( {V}_{C} + {V}_{th\_p} - {V}_{th\_n} )}^{2} \qquad ( 22 )$$

If both numerator and denominator of Eq. (21) are divided by ßₚ^{1/2}, and furthermore, V_{th_p} is defined as an absolute value to be expressed as a positive value, the result becomes the same as the already explained expression of Eq. (2).

For the sake of simplicity, the unintentional shoot-through current I_{C0} such as leakage current is assumed to be ignorable, because the unintentional shoot-through current I_{C0} can be regarded as being fully small compared with the peak value ΔI_{C} of the transient current variation illustrated in FIG. 8. If I_{C0}<<ΔI_{C}, Eq. (22) can be represented as the following Eq. (23) by using Eqs (19b) and (19c).

$$Δ {I}_{C} = \frac{1}{2} \frac{{β}_{n} {β}_{p}}{{β}_{n} + {β}_{p} + 2 \sqrt{{β}_{n} {β}_{p}}} {( {V}_{DD} - {R}_{C} Δ {I}_{C} + {V}_{th\_p} - {V}_{th\_n} )}^{2} \qquad ( 23 )$$

Also, by solving a quadratic equation of the peak value ΔI_{C} in the transient current derived from Eq. (23), the following Eq. (24) is obtained as the solution of the peak value ΔI_{C} of the transient current variation illustrated in FIG. 8.

$$Δ {I}_{C} = \frac{1}{{R}_{C}} [ \frac{{β}_{n} + {β}_{p} + 2 \sqrt{{β}_{n} {β}_{p}}}{{β}_{n} {β}_{p}} \frac{1}{{R}_{C}} + ( {V}_{DD} + {V}_{{th}_{- p}} - {V}_{{th}_{- n}} ) ] ↵ \pm \frac{1}{{R}_{C}} \sqrt{\begin{matrix}{[ \frac{{B}_{n} + {β}_{p} + 2 \sqrt{{β}_{n} {β}_{p}}}{{β}_{n} {β}_{p}} \frac{1}{{R}_{C}} + ( {V}_{DD} + {V}_{th\_p} - {V}_{th\_n} ) ]}^{2} - \\ {( {V}_{DD} + {V}_{th\_p} - {V}_{th\_n} )}^{2}\end{matrix}} \qquad ( 24 )$$

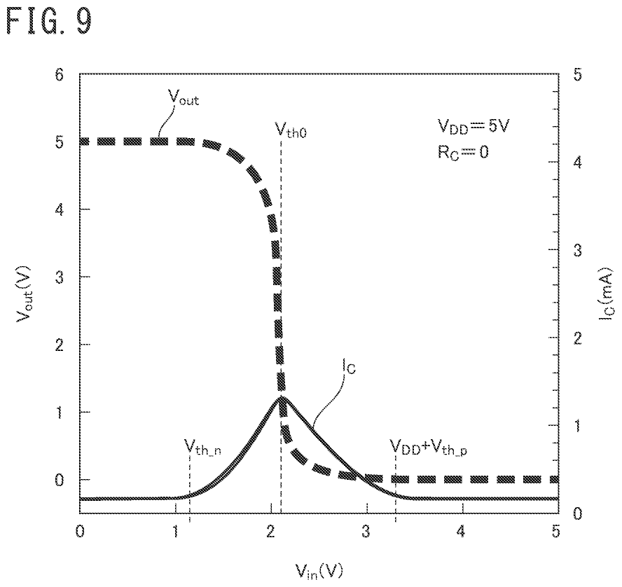

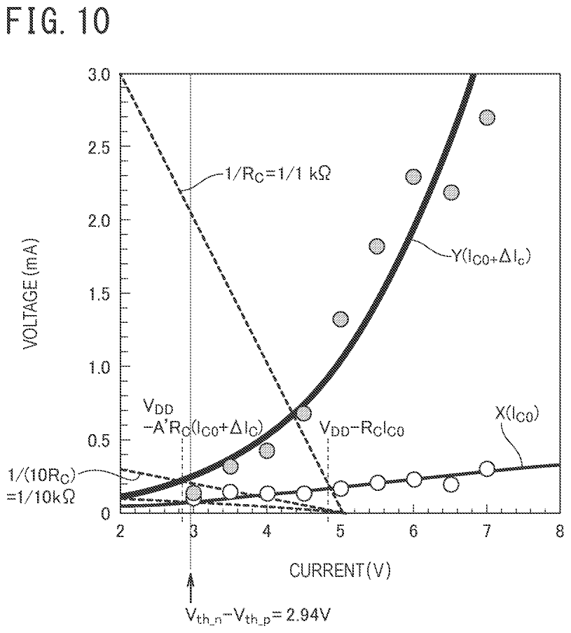

As already explained in Eq. (3), the simultaneous-conduction regime ΔVₜₕ₀ defines the voltages lying in the range spanning the length of the bottom side in the triangle by the solid line in FIG. 8. However, If we set V_{C}=V_{DD} in FIG. 8, the simultaneous-conduction regime ΔVₜₕ₀ will correspond to a length of a bottom side in a triangle represented by a solid line in FIG. 9.

ΔVₜₕ₀=V_{DD}+V_{th_p}−V_{th_n} (25a)

So, under the assumption of Eq. (25a), by using a conductance G_{C} of the resistive element R_{C} and an element-structure parameter γ, the following Eqs. (25b) and (25c) will be held.

G_{C}=1/R_{C} (25b)

γ=[βₙ+βₚ+2(βₙβₚ)^{1/2}]/(βₙβₚ) (25c)

Then, Eq. (24) can be simplified and represented as the following Eq. (26):

ΔI_{C}=G_{C}(γG_{C}+ΔVₜₕ₀)±G_{C}[G_{C}(γG_{C}+ΔVₜₕ₀)²−ΔVₜₕ₀)²]^{1/2} (26).

In view of Eq. (25a), Eq. (26) can be represented as the following Eq. (27) in a format of a function F(R_{C}, V_{DD}) of R_{C} and V_{DD}, by using the resistance value R_{C} of the resistive element R_{C}, such

ΔI_{C}=F(R_{C},V_{DD}) (27)

Practically, the resistance value of the resistive element R_{C} is recursively determined by linking the peak value ΔI_{C} of the transient current variation, the resistance value of the resistive element R_{C} and the power-supply voltage V_{DD} with each other as represented by Eq. (27), and using the experimental data. A curve X running on the lower side in FIG. 10 illustrates a relationship between the power-supply voltage V_{DD} and the unintentional shoot-through current I_{C0} when the input voltage is zero-volt. Also, a curve Y rising at the center in FIG. 10 is a graph illustrating a relationship between the power-supply voltages V_{DD} and shoot-through currents (I_{C0}+ΔI_{C}), when the shoot-through currents are flowing in the CMOS inverter, by setting the input voltages to flow the shoot-through currents.

The resistance values of the resistive elements R_{C} will be determined, by using a load curve indicated by a dashed line in the power-supply voltage versus shoot-through current characteristics exhibited in FIG. 10. The load curve will be expressed by following Eq. (28):

I=(1/R_{C})V (28).

An upper oblique line delineated on the upper side, which passes through a point (voltage: 2 volts; current: 3 milliamperes) and a point (voltage: 5 volts; current: 3 milliamperes) in FIG. 10 is a load curve intersecting a current axis at 3 milliamperes and a voltage axis at 5 volts in I-V characteristic diagram. And, the upper oblique line as the load curve assumes: V_{DD}=5 volts, R_{C}=1 kilo-ohms and a resistance-value setting-coefficient A′=10. In FIG. 10, a lower oblique line delineated on the lower side, which passes through a point (voltage 2 volts; current: 0.3 milliampere) and a point (voltage 5 volts; current: 0 milliampere) is a load curve of R_{C}=10 kilo-ohms, which intersects the current axis at 0.5 milliampere and the voltage axis at 5 volts in the I-V characteristic diagram.

Concretely, the curve X, which connects data points each of which is marked with open circles in FIG. 10, is a V_{DD}−I_{C0} curve that indicates a case of R_{C}=0, namely, a situation in which there is no resistive element R_{C} in FIG. 2. By the curve X, V_{DD}−I_{C0} curve is obtained which indicates the relationship between V_{DD} and I_{C0} at a condition of Vᵢₙ=0 volt. The curve Y, which connects filled circles (indicated by dots) in FIG. 10 is a curve in which measured data at a condition when the shoot-through current flows through the CMOS inverter are plotted, when the levels of Vᵢₙ belong to the effective drive span ΔV_{osc}, namely, the levels of Vᵢₙ lie in the range between the upper limit value (V_{th_c}+ΔV_{osc}/2) and the lower limit value (V_{th_c}−ΔV_{osc}/2). By the curve Y, which connects the filled circles in FIG. 10, the V_{DD} vs. (I_{C0}+ΔI_{C}) curve is obtained which indicates the relationship between V_{DD} and the (I_{C0}+ΔI_{C}). With V_{DD}−I_{C0} curve indicated by the curve X in FIG. 10 and the V_{DD} vs. (I_{C0}+ΔI_{C}) curve indicated by the curve Y as a base, when ΔI_{C} is multiplied by the A′, V_{DD} vs. (I_{C0}+A′ΔI_{C}) curve is calculated which indicates a relationship between V_{DD} and the (I_{C0}+A′ΔI_{C}).

And, as illustrated in FIG. 10, a load curve of the resistive element R_{C} is illustrated with respect to V_{DD}−I_{C0} curve and the V_{DD} vs. (I_{C0}+A′ΔI_{C}) curve. The resistance value of the resistive element R_{C} can be determined by selecting a resistance value of the resistive element R_{C}, which satisfies the conditions indicated by following Eqs. (29) and (30). Namely, the selection of the resistance value of the resistive element R_{C} shall be determined by a position of the intersection of V_{DD}−I_{C0} curve and the load curve, and by a position of the intersection of the V_{DD} vs. (I_{C0}+A′ΔI_{C}) curve and the load curve:

V_{DD}−R_{C}I_{C0}>V_{th_n}−V_{th_p} (29)

V_{DD}−R_{C}(I_{C0}+A′ΔI_{C})<V_{th_n}−V_{th_p} (30)

FIG. 10 illustrates a case of V_{th_n}−V_{th_p}=2.94 volts.

In addition, in the resistor-connected complementary transistor-circuit, the gate threshold V_{th_p} of the pMOS transistor Q_{P} and the gate threshold V_{th_n} of the nMOS transistor Q_{N} can be estimated from I_{C}−Vᵢₙ characteristics under a condition when the resistive element R_{C} is not inserted. For example, the gate threshold V_{th_p} and the gate threshold Vₜₕ, can be estimated by the simulation result in FIG. 8 and the measured data in FIG. 9. Also, since ΔI_{C}>>I_{C0}, V_{DD} vs. A′(I_{C0}+ΔI_{C}) curve can be used in place of the V_{DD} vs. (I_{C0}+A′ΔI_{C}) curve. Under the condition when ΔI_{C}>>I_{C0}, the desirable resistance value of the resistive element R_{C} can be obtained by multiplying the resistance value acquired from the load curve by A′, even if not multiplying ordinate of the V_{DD} vs. (I_{C0}+ΔI_{C}) curve by A′. The subject matter in the technical idea of the pulse generator pertaining to the first embodiment lies in the reduction in the potential levels of the higher-potential side node V_{C} of the CMOS inverter when the shoot-through current flows. Thus, the resistive element R_{C} is not always limited to the concrete circuit arrangement that is physically designed as the real circuit elements exemplified in FIG. 2, and it is natural that the resistive element R_{C} can be replaced with a mechanism or stray elements whose function is equivalent to the resistive element R_{C}. Thus, when the term of “the resistive element R_{C}” is referred in the explanation of the pulse generator pertaining to the first embodiment, the term of the resistive element R_{C} can include the various mechanisms each of which has an action, a behavior, and a performance equivalent to the resistive element R_{C}. As an example of the mechanism or stray elements whose action, behavior, or performance is equivalent to the resistive element R_{C}, there is a case in which inner stray resistance exists in a power supply, and there is a case of tracking delay caused by load fluctuation when an output impedance of a power-supply apparatus is not sufficiently larger than the load impedance. For example, even the fluctuation of the power-supply voltage in a step-up and step-down circuit of an AC adaptor can serve as the action, behavior, or performance equivalent to the resistive element R_{C}.

As mentioned above, according to the pulse generator pertaining to the first embodiment, the output circuit 11 for delivering the spike-train signals is implemented by the single-stage CMOS inverter, and to the CMOS inverter, the resistive element R_{C} is connected in series between the higher-potential power-supply V_{DD} and the pMOS transistor Q_{P}, and the resistor-connected complementary transistor-circuit is constructed. And, in light of the voltage drop caused by the resistive element R_{C}, with the swing-center potential V_{th_c} as represented by Eq. (12) as the reference potential, by applying the input voltage Vᵢₙ, which is minutely variated in the range between the upper limit value (V_{th_c}+ΔV_{osc}/2) and the lower limit value (V_{th_c}−ΔV_{osc}/2) of the effective drive span ΔV_{osc}, to the resistor-connected complementary transistor-circuit, it is possible to deliver the spike-train signals of which the pulse width and the frequency are controlled. Thus, according to the pulse generator pertaining to the first embodiment, since the circuit topology is simple and compact configuration, it is easy to install many pulse generators in the complex computer system, and it is possible to provide the pulse generator that can perform the control in which the fluctuations of the pulse width, the frequency and others are moderate, being controlled in a limited latitude.

### Neural Network

An example will be explained in which the pulse generator pertaining to the first embodiment is applied to a neuron circuit of a neural network. That is, hereafter, a neural network is explained in which the pulse generator pertaining to the first embodiment is used in a neuron circuit for transmitting and receiving information through voltage spike.

As a part of the structure is schematically illustrated in FIG. 12, a first neuron circuit 1A and a second neuron circuit 1B transmit and receive the information through a first output voltage Vₒᵤₜ₁ and a second output voltage Vₒᵤₜ₂ in a neural network such as SNN. Since the first neuron circuit 1A and the second neuron circuit 1B are equal in the configuration, here, the configuration of the first neuron circuit 1A is explained as an example.

As illustrated on the left side in FIG. 12, the first neuron circuit 1A includes a pulse generator 2 for transmitting voltage spikes, a detector 3 for detecting an input-information I, and a controller 4 for controlling the frequency and timings of the voltage spikes by the input-information I. The pulse generator 2 includes, for example, the pulse generator recited in the first embodiment, as explained in FIGS. 1 and 2.

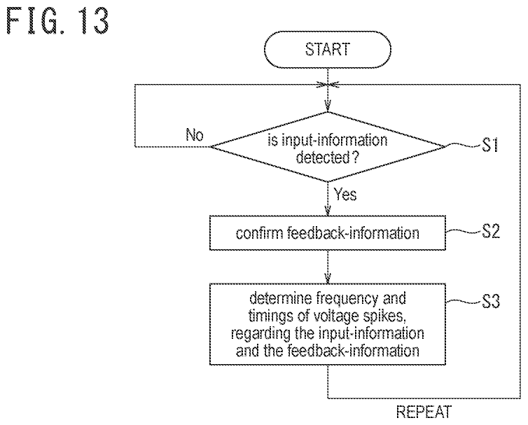

And, when detecting the specific input-information I, the detector 3 notifies the detection of the specific input-information I to the controller 4. As illustrated in Step S1 in FIG. 13, when receiving a notification (excitability) indicating the detection of the specific input-information I from the detector 3, the controller 4 checks a second voltage spikes (feedback information: inhibitory) from the second neuron circuit 1B, in Step S2. And, in Step S3, the controller 4 determines the frequency and timings of the voltage spikes (firing) as the first output voltage Vₒᵤₜ₁, by the specific input-information I and a second feedback information Vₒᵤₜ₂.

For transmitting the voltage spikes having the determined frequency and timings, the controller 4 applies an input voltage Vᵢₙ to the pulse generator 2 at a predetermined timing. In a period while receiving the input voltage Vᵢₙ, the pulse generator 2 supplies the voltage spikes as the first output voltage Vₒᵤₜ₁ to the second neuron circuit 1B.

In this way, although the controller 4 tries to deliver the voltage spikes ascribable to the specific input-information (excitability), the frequency and firing timing of the voltage spikes are adjusted by the feedback information (inhibitory). With the repetition of the operations, the output voltage Vₒᵤₜ₁ of the first neuron circuit 1A is converged in a direction in which the voltage spikes are delivered, or a direction in which the voltage spikes are not delivered. In recent years, attention is paid to the research of firing timings of spike pulses in the neuron circuit. However, by using the pulse generator recited in the first embodiment, it is possible to control the fluctuation of the frequency and timings of the firing of the spike pulses within a specific limited latitude and generate the spike pulses.

As mentioned above, according to the neural network pertaining to the application example of the first embodiment, it is possible to achieve AI computer architecture having a performance compatible to mammal-like brain, by using the compact pulse generator explained in FIGS. 1 and 2 to the first neuron circuit 1A and the second neuron circuit 1B. That is, even in a case that the huge number of pulse generators 2 are required such as the AI computer architecture, performance of which is addressing to a level compatible to the mammal-like brain, the large number of pulse generators can be monolithically integrated in a single chip, because the pulse generator 2 pertaining to the first embodiment is compactly structured. Thus, according to the pulse generator 2 pertaining to the first embodiment, it is possible to achieve robots, moving vehicles, mobile objects and others each of which has AI computer architecture whose information processing capability is improved more and more due to the neural network such as SNN where the huge number of pulse generators 2 are integrated.

### Second Embodiment

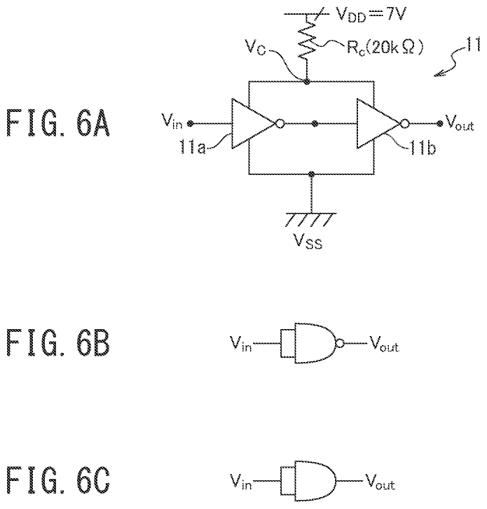

As “a complementary circuit”, an output circuit 11 pertaining to a second embodiment of the present invention encompasses a first CMOS inverter 11a and a second CMOS inverter 11b connected in parallel configured to implement a ladder-shaped two-stage structure, as illustrated in FIG. 6A. Similarly to the circuit diagram illustrated in FIG. 2, each of the first CMOS inverter 11a at the first stage (initial stage) and the second CMOS inverter 11b at the second stage includes a pMOS transistor Q_{P} and an nMOS transistor Q_{N}. However, in the pulse generator pertaining to the second embodiment, “the resistor-connected complementary transistor-circuit” is constructed, in which one resistive element R_{C}=20 kilo-ohms is commonly connected in series to a parallel circuit of the first CMOS inverter 11a and second CMOS inverter 11b, to implement the complementary circuit composed of double CMOS inverters. Both first CMOS inverter 11a and second CMOS inverter 11b, which implement the complementary circuit, share the resistive element R_{C} as a series-connected element, and realize the resistor-connected complementary transistor-circuit. And, as illustrated in FIG. 6A, both of the inverter 11a and the inverter 11b are connected between the higher-potential power-supply V_{DD} (V_{DD}=7 volts) and the ground potential (lower-potential power-supply), and thereby, implementing the output circuit 11 in the pulse generator pertaining to the second embodiment.

The operation of the first CMOS inverter 11a at the first stage (initial stage) in the pulse generator pertaining to the second embodiment can be described along the timing table illustrated in FIG. 3 used in the explanation of the pulse generator pertaining to the first embodiment as already explained. At first, in the voltage source 12 installed in the pulse generator pertaining to the second embodiment, a signal of sinusoidal wave with cos (ωt) is supposed to be superimposed on the DC component prescribed by Eq. (3) as the input voltage Vᵢₙ at time T0 in an initial condition, similarly to the timing table illustrated in FIG. 3. At time T0, a level of the sinusoidal wave of cos (ωt) of the input voltage Vᵢₙ prescribed by Eq. (3) is assumed to be a “H” level, which is higher than a swing-center potential V_{th_c} of the first CMOS inverter 11a at the first stage.

At time T0, the pMOS transistor in the first CMOS inverter 11a at the first stage is kept in cut-off state, while the nMOS transistor in the first CMOS inverter 11a is kept in conductive state. Thus, the output voltage Vₒᵤₜ of the first CMOS inverter 11a illustrated in FIG. 6A is “L≈0 V”. When the output voltage Vₒᵤₜ of the first CMOS inverter 11a becomes the voltage of the “L” level, the pMOS transistor in the second CMOS inverter 11b at the second stage transits to conductive state, while the nMOS transistor in the second CMOS inverter 11b is kept in cut-off state. Although the output voltage Vₒᵤₜ of the second CMOS inverter 11b becomes the “H” level, the higher-potential side node V_{C} defined as a connection node between the resistive element R_{C} and a common node of the first CMOS inverter 11a and the second CMOS inverter 11b is kept in the power-supply voltage V_{DD}=7 volts.

According to Eqs. (2) and (6), the inverter threshold Vₜₕ of each of the first CMOS inverter 11a and the second CMOS inverter 11b depends on the power-supply voltage V_{C} of each of the first CMOS inverter 11a and the second CMOS inverter 11b. That is, in the pulse generator pertaining to the second embodiment, the inverter threshold Vₜₕ of the first CMOS inverter 11a depends on the voltage V_{C} of the higher-potential side node V_{C} illustrated in FIG. 6A, and the swing-center potential V_{th_c} is also depending on the voltage V_{C} of the higher-potential side node V_{C}. Similarly to the behavior in the timing table illustrated in FIG. 3, when the input voltage Vᵢₙ fed from the voltage source 12 at time T1 has decreased to the value smaller than (V_{th_c}+ΔV_{osc}/2), in accordance with the sinusoidal wave of cos (ωt) prescribed by Eq. (3), the first CMOS inverter 11a is plunged into the operation region in the effective drive span ΔV_{osc}.

When the AC component of the input voltage Vᵢₙ swings at a speed slower than a time constant of the first CMOS inverter 11a, and the potential of the input voltage Vᵢₙ arrives to a level in the effective drive span ΔVᵢₙ an operation is started in which both pMOS and nMOS transistors in the first CMOS inverter 11a try to turn on. When the operation is started in which both pMOS and nMOS transistors in the first CMOS inverter 11a try to turn on is started, a displacement current is generated which is caused by gate capacitance such as a capacitance C_{GS} between gate and source in the pMOS transistor. Then, the displacement current induces a spike voltage by which the output voltage Vₒᵤₜ of the first CMOS inverter 11a is sharply risen to a value close to the voltage V_{C0}=V_{DD} of the original higher-potential side node V_{C}. In FIG. 6A, when the power-supply voltage is assumed to be V_{DD}=7 volts, similarly to the diagram illustrated in FIG. 5A, a value of the spike voltage is the similar level of the “H” level, which is slightly smaller than the power-supply voltage V_{DD}=7 volts. When the output voltage Vₒᵤₜ of the first CMOS inverter 11a arrives at the “H” level, the pMOS transistor of the second CMOS inverter 11b transits to cut-off state, and the nMOS transistor of the second CMOS inverter 11b transits to conductive state. Thus, the output voltage Vₒᵤₜ of the second CMOS inverter 11b illustrated in FIG. 6A becomes “L”.

Also, since the shoot-through current I_{C} flows through the first CMOS inverter 11a, at time T2, the potential of the higher-potential side node V_{C} begins to decrease similarly to the indication in Eq. (8). However, R_{C} of Eq. (8) is the resistance value of the resistive element R_{C}, and I is a current value of the shoot-through current I_{C} in the first CMOS inverter 11a. Then, when the potential of the higher-potential side node V_{C} decreases to V_{C1} at time T3, the inverter threshold Vₜₕ serving as the reference potential of the swing-center potential V_{th_c} in the first CMOS inverter 11a is reduced from the no-load inverter-threshold Vₜₕ₀, which is an initial value, to the under-load inverter-threshold Vₜₕ₁=f(V_{C1})<V_{th_c}.

At time T4, when a reference voltage necessary for the simultaneous-conductive state of the first CMOS inverter 11a has decreased to the under-load inverter-threshold Vₜₕ₁=f(V_{C1}), the input voltage Vᵢₙ becomes relatively larger than the under-load inverter-threshold Vₜₕ₁ of the first CMOS inverter 11a. As a result, the pMOS transistor in the first CMOS inverter 11a transits to cut-off state, and the nMOS transistor in the first CMOS inverter 11a is kept in conductive state. Thus, at time T5, the output voltage Vₒᵤₜ of the first CMOS inverter 11a will decrease toward “L”, and the shoot-through current I_{C} also decreases to zero.

When the output voltage Vₒᵤₜ of the first CMOS inverter 11a becomes the voltage of the “L” level, the pMOS transistor in the second CMOS inverter 11b transits to conductive state, and the nMOS transistor in the second CMOS inverter 11b transits to cut-off state, and the output voltage Vₒᵤₜ of the second CMOS inverter 11b becomes “H”. Since the shoot-through current I_{C} does not flow through the first CMOS inverter 11a, the higher-potential side node V_{C} is recovered from V_{c1}=(V_{DD}−R_{C}I) to the power-supply voltage V_{DD}=V_{C0}. Due to the recovery of the potential of the higher-potential side node V_{C}, at time T6, the inverter threshold Vₜₕ serving as the reference potential of the swing-center potential V_{th_c} of the first CMOS inverter 11a is risen and recovered from the under-load inverter-threshold Vₜₕ₁ at the timing of the T4 to the original no-load inverter-threshold Vₜₕ₀=f(V_{C0}).

At time T7 at which the inverter threshold Vₜₕ serving as the reference potential of the swing-center potential V_{th_c} of the first CMOS inverter 11a is returned to the original no-load inverter-threshold Vₜₕ₀, the input voltage Vᵢₙ again approaches the swing-center potential V_{th_c} of the first CMOS inverter 11a and becomes the same situation as the time T1. That is, since the situations at the timings T1 to T7 are repeated, the output voltage Vₒᵤₜ of the first CMOS inverter 11a is fluctuated, thereby transmitting the spike-train signals from the first CMOS inverter 11a. Thus, the spike-train signals transmitted from the first CMOS inverter 11a are inverted, and the inverted signals are delivered from an output terminal of the second CMOS inverter 11b. In the operation of the output circuit 11 in the pulse generator pertaining to the second embodiment, the inverter in which both pMOS and nMOS transistors become conductive states is only the first CMOS inverter 11a. Thus, without any inflow of the shoot-through current to the second CMOS inverter 11b, the operation similar to the usual CMOS inverter can be performed.

With the elapse of time, when the reduction of the sinusoidal wave of cos (ωt) at the second term on the right side in Eq. (3) is proceeded and the input voltage Vᵢₙ is decreased beyond (V_{th_c}−ΔV_{osc}/2), the input voltage Vᵢₙ is deviated from the effective drive span ΔV_{osc}. When the input voltage Vᵢₙ has decreased to a potential deviated from the effective drive span ΔVᵢₙ the nMOS transistor Q_{N} transits to cut-off state. That is, even at the timing, at which he potential of the higher-potential side node V_{C} is recovered to the voltage V_{C0} of the original higher-potential side node V_{C} after the potential of the higher-potential side node V_{C} has decreased to V_{C1} by the shoot-through current I_{C}, because the potential of the higher-potential side node V_{C} is deviated from the effective drive span ΔV_{osc} of the first CMOS inverter 11a, the nMOS transistor Q_{N} of the first CMOS inverter 11a is kept in cut-off state. When the pMOS transistor Q_{P} is kept in conductive state and the nMOS transistor Q_{N} is kept in cut-off state, the potential of the output voltage Vₒᵤₜ is kept at the values of the “H” level close to the voltage V_{C0}=V_{DD} of the original higher-potential side node V_{C}.

If the nMOS transistor Q_{N} of the first CMOS inverter 11a is kept in cut-off state, the spike-train signals are not delivered from the first CMOS inverter 11a, and the signal of the “H” level is delivered as the output signal from the first CMOS inverter 11a. That is, similarly to the time periods after the completions of the generations of the spike trains in the second and fourth oscillation periods from the left in FIG. 5A, although the output voltages Vₒᵤₜ from the first CMOS inverter 11a are close to the power-supply voltage V_{DD}, the output voltages Vₒᵤₜ re located at the “H” level smaller than the power-supply voltage V_{DD}.

When the output voltage Vₒᵤₜ of the first CMOS inverter 11a arrives at the voltage of the “H” level, the pMOS transistor in the second CMOS inverter 11b transits to cut-off state, the nMOS transistor in the second CMOS inverter 11b transits to conductive state, and the output voltage Vₒᵤₜ of the second CMOS inverter 11b becomes “L=0 V”. Since the shoot-through current I_{C} does not flow through the first CMOS inverter 11a, the higher-potential side node V_{C} is recovered from V_{C1}=(V_{DD}−R_{C}I) to the power-supply voltage V_{DD}=V_{C0}.

With the further elapse of time, the amplitude of the sinusoidal wave of cos (ωt) at the second term on the right side in Eq. (3) becomes the minimum value. After the timing of the minimum value, the amplitude begins to be slowly increased from the minimum value. When the amplitude of the sinusoidal wave of cos (ωt) represented at the second term on the right side in Eq. (3) is gradually increased from the minimum value and the input voltage Vᵢₙ exceeds (V_{th_c}−ΔV_{osc}/2), the input voltage Vᵢₙ is plunged into the levels in the effective drive span ΔV_{osc} of the first CMOS inverter 11a. When the variation of the input voltage Vᵢₙ is increased to a value at which the input voltage Vᵢₙ is plunged into the levels in the effective drive span ΔV_{osc} of the first CMOS inverter 11a, both of the pMOS transistor Q_{P} and the nMOS transistor Q_{N} in the first CMOS inverter 11a become conductive states. And, similarly to the situations in the first and third oscillation periods from the left in FIG. 5A, the oscillations by the repeated operations of the pMOS transistor Q_{P} in the conductive states is generated, thereby generating clusters of spike trains in each of the first and third oscillation periods.

That is, since the output voltage Vₒᵤₜ of the first CMOS inverter 11a is fluctuated and the spike-train signals are delivered from the first CMOS inverter 11a, the spike-train signals transmitted from the first CMOS inverter 11a are inverted are delivered from the output terminal of the second CMOS inverter 11b. With the further elapse of time, the sinusoidal wave of cos (ωt) represented at the second term on the right side in Eq. (3) become large and the input voltage Vᵢₙ is increased to a value exceeding (V_{th_c}+ΔV_{osc}/2) and deviated from the effective drive span ΔVᵢₙ the generation of the spike-train signals from the first CMOS inverter 11a is stopped. That is, in a case that in association with the increase of the sinusoidal wave of cos (ωt) so that the input voltage Vᵢₙ becomes the “H” level exceeding (V_{th_c}+ΔV_{osc}/2), the pMOS transistor Q_{P} is kept in cut-off state even when the potential of the higher-potential side node V_{C} has decreased to V_{C1} by the shoot-through current I_{C}, because the input voltage Vᵢₙ is higher than the voltage of the effective drive span ΔV_{osc} of the first CMOS inverter 11a.

That is, similarly to the timings at the right edges of spike-trains in the first and third oscillation periods from the left in FIG. 5A, when the pMOS transistor Q_{P} in the first CMOS inverter 11a enters cut-off state, after the first and third oscillation periods, the pMOS transistor Q_{P} in the first CMOS inverter 11a is kept in cut-off state, and the nMOS transistor Q_{N} is kept in conductive state. That is, in a case that the input voltage Vᵢₙ is increased to the “H” level exceeding (V_{th_c}+ΔV_{osc}/2), the pMOS transistor Q_{P} in the first CMOS inverter 11a is kept in cut-off state, and the nMOS transistor Q_{N} is kept in conductive state. That is, similarly to the time period after the completion of the generation of the spike trains in the first and third oscillation periods from the left in FIG. 5A, the output signals from the first CMOS inverter 11a is still “L≈0 V”. In the first and third oscillation periods, in which the output signals from the first CMOS inverter 11a is kept in “L≈0 V”, the output signals from the second CMOS inverter 11b is kept in the “H” level.

With the further elapse of time, as represented by Eq. (3), with regard to the input voltage Vᵢₙ, after passing through the maximum value, the variation of the sinusoidal wave of cos (ωt) begins to decrease again and slowly. Then, when the input voltage Vᵢₙ has decreased to the value smaller than (V_{th_c}+ΔV_{osc}/2), the input voltage Vᵢₙ is plunged into the levels in the effective drive span ΔV_{osc} of the first CMOS inverter 11a. Since the following operations are the same explanation as the already-described operations in the first embodiment, the duplicate explanation is omitted. In the pulse generator recited by the first embodiment, the technical feature that “the fluctuating signals”, which are controlled by the minute variations of the input voltage Vᵢₙ, can be obtained has been already explained, as exemplified in FIG. 5B. The fluctuations such as the pulse widths, the pulse intervals, the pulse-firing timings, and others, which are generated in the first CMOS inverter 11a are delivered to the input terminal of the second CMOS inverter 11b, and the inverted spike-train signals of the first CMOS inverter 11a are delivered from the output terminal of the second CMOS inverter 11b.

Thus, according to the pulse generator pertaining to the second embodiment, the variations of the pulse widths, the pulse intervals, the pulse-firing timings, and others are controlled as the fluctuations, which are somewhat limited in a specific latitude, and the fluctuations are delivered from the second CMOS inverter 11b as output signals, similarly to the pulse generator of the first embodiment. Because the variations are confined in the specific latitude, the variations are distinguishable from the perfectly random fluctuations, and therefore, the output signals having a feature being distinguishable from the perfectly random fluctuations are delivered from the second CMOS inverter 11b. Even in the pulse generator pertaining to the second embodiment, the macro “fluctuations”, in which clusters of the spike-train signals are generated intermittently and periodically, are generated similarly to the waveforms illustrated in FIG. 5A. And furthermore, according to the pulse generator pertaining to the second embodiment, the micro “fluctuations”, in which the pulse widths are altered by the minute variations in the input voltage Vᵢₙ, are generated as illustrated in FIG. 5B. That is, according to the pulse generator pertaining to the second embodiment, when the values of the input voltage Vᵢₙ entering to the first CMOS inverter 11a minutely swing near the swing-center potential V_{th_c} of the first CMOS inverter 11a as represented by Eq. (12), the fluctuating signals, in which the pulse width and the pulse interval are controlled within a desirable latitude, can be provided from the second CMOS inverter 11b.

According to the pulse generator pertaining to the second embodiment, the first CMOS inverter 11a and the second CMOS inverter 11b are connected in tandem (connected in parallel) in double stages, and the resistor-connected complementary transistor-circuit is accordingly implemented, which can improve the reproducibility of the pulse characteristics of the spike-train signals. That is, according to the pulse generator pertaining to the second embodiment, it is possible to stably generate the spike-shaped pulsed signals that has the fluctuations of the predetermined pulse width, pulse interval, pulse-firing timing, and others. The subject matter means that the pulse generator pertaining to the second embodiment can provide “the fluctuating signals in which the pulse width, the pulse interval and others are controlled within a desirable latitude” as the fluctuations, of which reproducibility is improved. For example, as illustrated in FIG. 7, a relationship between the swing-center potentials V_{th_c} of the input voltages Vᵢₙ exhibited in abscissa and spike train frequencies of the output voltages Vₒᵤₜ exhibited in ordinate can be made approximately equal, independently of the event numbers of spike-train signals occurrences—a first occurrence, a second occurrence and a third occurrence—.

In FIG. 6A, the power-supply voltage of V_{DD}=7 volts and the resistance value R_{C}=20 kilo-ohms assigned to the resistive element R_{C} are assumed for the resistor-connected complementary transistor-circuit in the pulse generator pertaining to the second embodiment. As represented by Eq. 7(b), for determining the swing-center potential V_{th_c} of the input voltage Vᵢₙ, which enables the spike-train signals composed of spike-shaped pulses to be generated, it is necessary to consider the dependency of the voltage-adjustment parameter ΔV_{mod_H} on the resistance values of the resistive element R_{C}. That is, the input voltages Vᵢₙ for generating the spike-train signals depends on the resistance values of the resistive element R_{C}, which will be explained later with reference to FIG. 11. For example, a range of the input voltages Vᵢₙ=1.403 volts to 1.430 volts illustrated in FIG. 7 is lower than the central value (V_{DD}/2=3.5 volts) in between the higher-potential power-supply V_{DD} and the lower-potential power-supply (ground potential=0 volt) illustrated in FIG. 6A, by 2 volts (≈57 percent) or more for a case of the resistance value R_{C}=20 kilo-ohms. Data indicating the input voltage Vᵢₙ dependency of the repetition frequency (spike train frequency) of the spike trains illustrated in FIG. 7 indicates that the frequencies can be controlled in a range of 320 kHz to 740 kHz, by swinging the values of the second terms on the right sides in Eq. (3) or (12) in the range of 1.403 volts to 1.430 volts, under a condition that the swing-center potential V_{th_c} necessary for the simultaneous-conductive state is set as a fixed value.

As mentioned above, the inverter in which both pMOS and nMOS transistors of the output circuit 11 in the pulse generator pertaining to the second embodiment turn into the simultaneous-conductive state is only the first CMOS inverter 11a. Thus, the shoot-through current does not flow through the second CMOS inverter 11b, except for an initial state. For example, I_{C01} is defined as a value of a shoot-through current I_{C1} at the time of the initial state (for example, Vᵢₙ=0 volt) of the first CMOS inverter 11a, and I_{C02} is defined as a value of a shoot-through current I_{C2} at the time of the initial state (for example, Vᵢₙ=0 volt). And, if the initial state is assumed to be I_{C01}=I_{C02}=I_{C0}, it is possible to apply all of theories, which are explained with Eqs. (13) to (28) for the oscillation conditions of the pulse generator of the first embodiment, to the pulse generator pertaining to the second embodiment, because it is enough to focus to only the shoot-through current of the first CMOS inverter 11a.

Thus, by using the method similar to FIG. 10 used in the explanation of the pulse generator of the first embodiment, and focusing to only the characteristics and operation of the first CMOS inverter 11a, it is possible to experimentally determine the range of the resistance values of the resistive elements R_{C} that enables the pulses in the pulse generator pertaining to the second embodiment. As the output circuit 11, although a double-stage CMOS inverter is illustrated in an insertion view on the upper right portion in FIG. 11, the insertion view on the upper right portion in FIG. 11 differs from the circuit topology of the power-supply voltage V_{DD}=7 volts illustrated in FIG. 6A in that the power-supply voltage of the higher-potential power-supply V_{DD} is V_{DD}=5 volts in the insertion view. In FIG. 11, ordinate indicates the values of the swing-center potentials V_{th_c} of the input voltages Vᵢₙ when the spike-train signals composed of spike-shaped pulses can be generated. However, as the experimental results illustrated in FIG. 11, the spike-train signals can be obtained in a region between 300 ohms and 100 kilo-ohms as the resistance values R_{C_osc} of the resistive element R_{C}. The experimental results illustrated in FIG. 11 indicate that proper values of the swing-center potentials V_{th_c} of the input voltages Vᵢₙ illustrated on ordinate are decreased with the increase of the resistance values of the resistive elements R_{C} illustrated on abscissa. Thus, depending on the variation of the resistance values of the resistive elements R_{C}, it is necessary to alter the preset values of swing-center potential V_{th_c}, which is represented at the first term on the right side in Eq. (3). It is necessary to pay careful attention to a situation that a range of input voltages Vᵢₙ=1.91 volts to 1.11 volts, exhibited on ordinate in FIG. 11, indicates a resistance value dependency of the input voltages Vᵢₙ. As illustrated in FIG. 11, the range indicating the resistance value dependency of the input voltages Vᵢₙ lies in a zone lower by 20 percent or more compared with the central value (V_{DD}/2=2.5 volts) in between the higher-potential power-supply V_{DD} and the lower-potential power-supply (ground potential=0 volt), and the potential levels of the zone is 2 volts or less. Characteristics that the appropriate values of the input voltages Vᵢₙ illustrated in FIG. 11 are decreasing together with the resistance values of the resistive elements R_{C} indicate the dependency on the resistance values of the resistive elements R_{C} of the voltage-adjustment parameter ΔV_{mod_H} represented by Eq. (7b).

In addition, if we define the appropriate resistance values of the resistive elements R_{C} that enables the pulse generation in the pulse generator pertaining to the second embodiment as R_{C_osc_mes}, the theoretical value R_{C_osc_mes} will be estimated from FIG. 10 base upon the theoretical equations used in the explanation of the pulse generator of the first embodiment, and the theoretical values of R_{C_osc_mes}=750 ohms to 30 kilo-ohms can be obtained. In the examples indicated in the pulse generator pertaining to the second embodiment, the values of R_{C_osc}=300 ohms to 100 kilo-ohms are acquired from the experimental results illustrated in FIG. 11. Then the range of experimentally determined values is larger than the range of theoretical values of R_{C_osc_mes}=750 ohms to 30 kilo-ohms, which is estimated from FIG. 10 and the above-mentioned theoretical equations. That is, not only the theoretical value but also the experimental confirmation is required for the dependency on the resistance values of the resistive elements R_{C} of the voltage-adjustment parameter ΔV_{mod_H} represented by Eq. (7b).

As mentioned above, the output circuit 11 pertaining to the second embodiment has the configuration of the resistor-connected complementary transistor-circuit in which the complementary circuit encompasses the first CMOS inverter 11a and the second CMOS inverter 11b, which are connected in parallel in the shape of ladder. Furthermore, the resistive element R_{C} is connected in series between the higher-potential power-supply V_{DD} and the pMOS transistor Q_{P} in each of the complementary circuits. And, by applying the input voltage Vᵢₙ, which has the potential levels lying in the effective drive span ΔV_{osc} with the swing-center potential V_{th_c} at a center, to the first CMOS inverter 11a at the first stage (initial stage), the spike-train signals, of which the pulse widths and the frequencies are controlled, can be delivered from the second CMOS inverter 11b at the second stage. Because the circuit topology represents a simple and compact configuration as illustrated in FIG. 6A, it is possible to assemble a huge number of pulse generators to be easily installed in the complex computer system. Furthermore, it is possible to control the fluctuations of the pulse widths, the frequencies, and others to be moderate such that the fluctuations are confined in a specific limited latitude. In addition, the stage number of the CMOS inverters implementing the complementary circuit, in a topology of the ladder-shaped parallel connection, building up the output circuit 11 in the pulse generator pertaining to the second embodiment is not limited to double stages, and triple stages or more stages can be used.

Also, the circuit topology of the complementary circuit implementing the output circuit 11 is not limited to the tandem connection of the simple CMOS inverters as illustrated in FIG. 6A. The technical idea of the pulse generators pertaining to the second embodiment can be applied to various logic gates if a complementary circuit has a circuit topology including a CMOS inverter in some way. For example, with regard to the complementary circuit implemented by a double-input negated logical-conjunction (NAND) gate, in which double-inputs are commonly connected as illustrated in FIG. 6B, by connecting a resistive element in series to a power supply side of a complementary circuit, it is confirmed to be able to generate pulsed signals having the fluctuations and improve the reproducibility of the fluctuations, similarly to the experimental results illustrated in FIG. 7. The complementary circuit implemented by a double-input NAND circuit illustrated in FIG. 6B is constructed in which one nMOS transistor and one pMOS transistor are added to a negation (NOT) circuit as is well known. That is, double pMOS transistors are arranged in parallel on a higher-potential power-supply side, and double nMOS transistors are connected in series to a connection node of the double pMOS transistors. Thus, the CMOS structures are constructed so that the series-connected nMOS transistors and one of the pMOS transistors are paired one by one to implement corresponding input terminals, although the double input terminals are short-circuited to implement a single input terminal. The resistive element is connected between a connection node of source electrodes of each of the double pMOS transistors and the higher-potential power-supply, and a connection node of drain electrodes of each of the double pMOS transistors and a drain electrode of an upper nMOS transistor are connected to each other to serve as an output terminal. Because the double input terminals of the series-connected nMOS transistors are short-circuited to implement a single input terminal, the double nMOS transistors serves as a single nMOS transistor. Hence, similarly to the complementary circuit illustrated in FIG. 6A, since the shoot-through current flows through the CMOS circuit, the spike pulses is repeatedly generated.

Moreover, the technical idea of the pulse generator pertaining to the second embodiment can be similarly applied to another complementary circuit implemented by a double-input logical-conjunction (AND) gate in which double-inputs are commonly connected as illustrated in FIG. 6C. That is, regarding the complementary circuit illustrated in FIG. 6C, the inventors of the present invention have confirmed that by connecting a resistive element in series to a power supply side of the complementary circuit, it is possible to generate the pulsed signals having the fluctuation and generate the pulsed signals having the “fluctuation” in which reproducibility is excellent, similarly to the experimental result illustrated in FIG. 7. The complementary circuit illustrated in FIG. 6C corresponds to the structure in which an input terminal of the CMOS inverter is connected to the output terminal of the double-input NAND circuit illustrated in FIG. 6B. Thus, sine the shoot-through current flows through the CMOS circuit on the NAND circuit side located on the input side, it is possible to generate the spike pulses having the “fluctuation” in which reproducibility is excellent, by the complementary circuit illustrated in FIG. 6C. Also, similarly to the complementary circuit which encompasses the tandem connection of the CMOS inverters illustrated in FIG. 6A, it may be easily understand the effectiveness of the reproducibility improvement caused by the additional tandem connection of the CMOS inverter to the NAND to implement the AND gate illustrated in FIG. 6C.

Also, a subject matter in the technical idea pertaining to the pulse generator of the second embodiment lies in the reduction of the potential levels at the higher-potential side node V_{C} of the complementary circuit, when the shoot-through current flows, similarly to the pulse generator of the first embodiment. Thus, the resistive element R_{C} is not always limited to the concrete circuit arrangement that is physically designed as the real circuit elements exemplified in FIG. 6A, and it is natural that the resistive element R_{C} can be replaced by unintentional mechanism or stray elements whose action, behavior, or performance is equivalent to the resistive element R_{C}. Thus, in the explanation of the pulse generator pertaining to the second embodiment, the resistive element R_{C} shall include the mechanism or the stray elements having the action, behavior, and performance equivalent to the resistive element R_{C}. And therefore, as to the fluctuations of the power-supply voltage will serve as a contrastive circuit element equivalent to the resistive element R_{C}.

Similarly to the application of the pulse generator of the first embodiment, the pulse generator pertaining to the second embodiment can be also applied to the neural network in which information is transmitted and received through the voltage spikes. That is, similarly to the circuit diagram illustrated in FIG. 12, the first and second neuron circuits transmit and receive the information through the corresponding first and second output voltages, in the neural network. The first and second neuron circuits have the same configuration as each other. However, the first neuron circuit includes voltage-spike generator for generating voltage spikes, a detector for detecting input-information, and a controller for controlling the frequency and timings of the voltage spikes by the input-information, similarly to the illustration on the left side in FIG. 12.

The voltage-spike generator includes the pulse generator pertaining to the second embodiment, for example, which has the double-stage CMOS inverter as explained in FIG. 6A. And, when detecting the specific input-information, the detector in the neural network pertaining to the second embodiment notifies the specific input-information to the controller. Similarly to the process flows illustrated in Steps S1 to S3 in FIG. 13, the controller applies an input voltage to the voltage-spike generator at a predetermined timing, configured to deliver the voltage spikes having the determined frequency and timings. While receiving the input voltage, the voltage-spike generator supplies the voltage spikes as the output voltage to the second neuron circuit. That is, although the controller tries to deliver the voltage spikes ascribable to the specific input-information (excitability), the frequency and firing timing of the voltage spikes are adjusted by the feedback information (inhibitory). With the repetitions of the above operations, the output voltages of the first neuron circuit are converged in directions in which the voltage spikes are delivered, or directions in which the voltage spikes are not delivered.

As mentioned above, according to the neural network pertaining to the application example of the second embodiment, by using the compact pulse generators as exemplified in FIGS. 6A, 6B and 6C as the first and second neuron circuits, each of which implements a part of the pulse generator, a very many voltage-spike generators can be integrated in a single chip, because the size of voltage-spike generators pertaining to the second embodiment is compact, even under a requirement that a huge number of voltage-spike generators are required. Thus, according to the voltage-spike generator pertaining to the second embodiment, by implementing the neural network such as the SNN in which the huge number of voltage-spike generators are integrated, it is possible to achieve the robots, moving vehicles, mobile objects, and others each of which includes AI computer architecture whose information-processing capability is improved more and more.

### OTHER EMBODIMENT

As described above, the first and second embodiments of the present invention have been described, but because Specifications and Drawings implement a mere part of the disclosure of the present invention, and it should not be understood that Specifications and Drawings are intended to limit the scope of the present invention. Various alternative embodiments, examples and operational techniques will become apparent to those skilled in the art from the above disclosure. For example, in the pulse generators pertaining to the first and second embodiments, the situations are explained in which the resistor-connected complementary transistor-circuit is implemented by the complementary circuit whose lower voltage side terminal is connected to the lower-potential power-supply, and the resistive element connected between the higher-potential power-supply and the higher voltage side terminal of the complementary circuit. However, the connection topology illustrated in FIG. 2 is merely exemplification. In reverse, the resistor-connected complementary transistor-circuit may be implemented by the complementary circuit whose higher voltage side terminal is connected to the higher-potential power-supply, and the resistive element is connected between the lower-potential power-supply and the lower voltage side terminal of the complementary circuit. In this case, instead of the higher-potential side node in the pulse generators pertaining to the first and second embodiments, “a lower-potential power-supply side node” is defined by a connection node between the lower voltage side terminal of the complementary circuit and the resistive element.

In the pulse generator pertaining to other embodiment in which the resistive element is connected between the lower-potential power-supply and the lower voltage side terminal of the complementary circuit, the right side in Eq. (7a) is rewritten as the following Eq. (31).

V_{th_c}=Vₜₕ₀+ΔV_{mod_L} (31)

ΔV_{mod_L} represented at the second term on the right side in Eq. (31) is the voltage-adjustment parameter, which is experimentally determined in order to set the swing-center potential V_{th_c}, is similar to ΔV_{mod_H} represented at the second term on the right side in Eq. (7a). Similarly to the relation represented by Eq. (7b), the voltage-adjustment parameter ΔV_{mod_L} prescribed by Eq. (31) varies in view of the resistance value of the resistive element R_{C}. Therefore, even in the pulse generator pertaining to the other embodiment, similarly to the pulse generators pertaining to the first and second embodiments, there is a case that in view of the resistance value of the resistive element R_{C}, the swing-center potential V_{th_c} is set to a considerably high value equal to or more than 20 percent of V_{DD}/2, as compared with the central value (V_{DD}/2) of the voltage between the higher-potential power-supply and the lower-potential power-supply. If the swing-center potential V_{th_c} is set to the considerably high value, even in the pulse generator pertaining to the other embodiment, the input voltage Vᵢₙ, required to deliver the spike-train signals, becomes a considerably high value, as compared with the central value (V_{DD}/2) of the voltage between the higher-potential power-supply and the lower-potential power-supply.

In the description of the pulse generators pertaining to the first and second embodiments in the explanation of FIG. 5B and the like, it has been explained that “the fluctuating signals”, in which the variations of the pulse widths, pulse intervals, pulse-firing timings, and others are somewhat controlled in a specific limited latitude, are generated by the minute variation of the input voltage Vᵢₙ. The “fluctuating signals” can be applied to “an amoeba computer” as described in JP Application No. 2020-184993 in which one of the present inventors is included as a co-inventor.

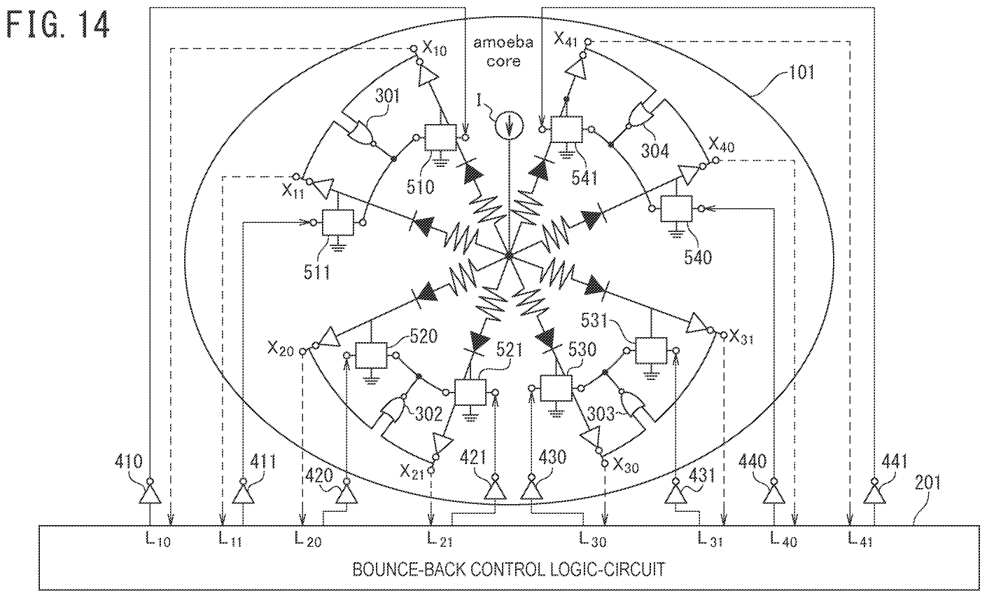

In the amoeba computer, it is possible to search for the solutions of a problem that searches for the optimal solution of various scheduling and combinations quickly and efficiently, by utilizing the probabilistic behaviors derived from “the fluctuation of a device” whose hint is received from the fluctuating behaviors of living organism or animate beings. For example, in the “amoeba-inspired electronic computer” mimicking behaviors of a single-celled amoeba as illustrated in FIG. 14, it is possible to provide a method that gets a suitable pattern quickly and surely, as compared with a conventional Neumann-computer, by utilizing the probabilistic operation obtained from the fluctuation of the pulse generator pertaining to the first or second embodiment, as “the fluctuation of a device”.

The amoeba core as the living organism wants to stretch as many legs as possible to outer wards in order to maximize the absorption amount of nutrients. On the other hand, the single-celled amoeba shrinks the legs when light is irradiated to the single-celled amoeba. If adopting a feedback rule, in which the on/off of light irradiations are updated by the shapes of the single-celled amoeba—the states of expansions and contractions of the legs—, the amoeba core illustrated in FIG. 14 searches for an optimal solution or sub-optimal solutions of the combinatorial optimization problem, in a process in which the single-celled amoeba is deformed by carrying out trial-and-errors configured to extend only a combination of legs that can minimize the risks of the light irradiations. In “amoeba-based computer”, a plurality of freely deforming legs in the single-celled amoeba, and a portion serving as the hub (center) of the plurality of legs memorize the experiences of the light irradiations. That is, the deformations of legs and the portion serving as the hub of the legs generate suitable “probabilistic fluctuations”, responding to optical stimuli, through the complex spatiotemporal oscillation dynamics of large free degrees in the plurality of legs. And the probabilistic fluctuations in the amoeba-based computer achieve the effectiveness similar to the quantum annealing of a quantum computer.

FIG. 14 exemplifies a structure of an amoeba core 101 embracing octuple pseudopodia-units, each of which has a series circuit implemented by a resistor and a diode, corresponding to a structure of a single-celled amoeba having octuple legs. In amoeba core 101, the octuple pseudopodia-units are radially arrayed. Input terminals of a double-input NOR gate 301 are connected between a pair of an output terminal X_{1.0} and an output terminal X_{1.1} which correspond to double legs of the single-celled amoeba responsible for determining a value of a variable x₁. Similarly, input terminals of double-input NOR gates 302, 303 and 304 are connected between a pair of an output terminal X_{2.0} and an output terminal X_{2.1} which are responsible for determining a value of a variable x₂, between a pair of an output terminal X_{3.0} and an output terminal X_{3.1} which are responsible for determining a value of a variable x₃, and between a pair of an output terminal X_{4.0} and an output terminal X_{4.1} which are responsible for determining a value of a variable x₄, respectively. When inhibition signals referred to as output-adjusting signals (bounce-back signals) are applied, the octuple pseudopodia-units illustrated in FIG. 14 are electrically shrunk, and the output voltages are decreased. And when the inhibition signals are not applied, the octuple pseudopodia-units are electrically extended, and the output voltages are increased. However, similarly to the single-celled amoeba that is the living organism, even when the pseudopodia-units are electrically extended and the output voltages are increased, the “fluctuating actions” that are not extended are generated at a constant fluctuating probability. In the amoeba-inspired electronic computer, by mimicking the behavior of the single-celled amoeba, “the fluctuating probability” is provided non-uniformly from the outside.

The amoeba core 101 searches for the solution while repeating the trial-and-errors, in which all the legs are extended and shrunk in simultaneous parallel scheme, under an environment in which undesirable state-transitions are prohibited by bounce-back rules delivered by a bounce-back control logic-circuit 201. And, the solution is discovered when all of the legs to which inverted signals of bounce-back signals L_{1.0}, L_{1.1}, . . . , L_{4.0}, L_{4.1} from the bounce-back control logic-circuit 201 are not applied arrives at a stable state in which all of the legs are kept in an extending state. In order to solve a problem of N variables, 2N amoeba legs are required. However, in FIG. 14, each of terminals at tip sides of octuple legs of the amoeba core connected to the bounce-back control logic-circuit 201 is grounded through input/output-rule circuits 510, 511; 520, 521; 530, 531; 540, 541, and a value of an output of each of output terminals X_{1.0}, X_{1.1}, . . . , X_{4.0}, X_{4.1} of the octuple pseudopodia-units is determined.

Since the pulse generator pertaining to the first or second embodiment is built in each of the input/output-rule circuits 510, 511; 520, 521; 530, 531; 540, 541 illustrated in FIG. 14, it is possible to generate the fluctuation necessary for the amoeba-inspired electronic computer. The necessary fluctuation means that, although fluctuation is required to be obtained to the generation of the spike-train signals used in an electronic amoeba circuit, the fluctuation is controlled within a desirable latitude. The pulse generators pertaining to the first and second embodiments can provide “the necessary fluctuation” because the fluctuation of the spike-train signals can be controlled within the desirable range. Especially, a feature that the pulse generator pertaining to the first or second embodiments embraces the fluctuations in the pulse-firing timing is important for the circuit operation of the amoeba core 101 illustrated in FIG. 14. That is, in a circuit in each of the input/output-rule circuits 510, 511; 520, 521; 530, 531; 540, 541 used in the amoeba core 101 illustrated in FIG. 14, since start timings are different even if pulse periods are equal, the fluctuations in the pulse-firing timing serve as functions that work positively for solution search in a computer system using the amoeba core 101. Also, since the pulse generators pertaining to the first and second embodiments is compact configuration in structure, the huge number of fluctuation generation devices corresponding to various variables can be assembled as integrated circuits. Thus, the pulse generators pertaining to the first and second embodiments are preferable for the applications to solution searching systems by the electronic amoeba circuits.

For example, the output terminal of the double-input NOR gate 301 placed between the output terminal X_{1.0} and output terminal X_{1.1} of the pseudopodia-unit responsible for determining the value of the variable x₁ is entered to a second input terminal of the input/output-rule circuit 510 placed between the output terminal X_{1.0} and the ground potential, and also entered to a second input terminal of the input/output-rule circuit 511 of the output terminal X_{1.1} simultaneously. And, as illustrated in FIG. 14, an inverted signals of the bounce-back signals (output-adjustment signals) L_{1.0} is entered through an inverter 410 to a first input terminal of the input/output-rule circuit 510 of the output terminal X_{1.0} of the pseudopodia-unit, and the necessary fluctuation is generated. Also, an inverted signals of the bounce-back signals L_{1.1} is entered through an inverter 411 to a first input terminal of the input/output-rule circuit 511 of the output terminal X_{1.1} of the pseudopodia-unit, and the necessary fluctuation is generated. And, respective output signals from the output terminal X_{1.0} and the output terminal X_{1.1} of the pseudopodia-unit are entered to the bounce-back control logic-circuit 201.

Similarly, the output terminal of the double-input NOR gate 302 connected between the output terminal X_{2.0} and the output the terminal X_{2.1} which are responsible for determining the value of the variable x₂ is entered to both of a second input terminal of the input/output-rule circuit 520 of the output terminal X_{2.0} and a second input terminal of the input/output-rule circuit 521 of the output terminal X_{2.1}, and the necessary fluctuation is generated. Moreover, inverted signals of the bounce-back signals L_{2.0} and the bounce-back signals L_{2.1} are fed through an inverter 420 and an inverter 421 to first input terminals of the input/output-rule circuit 520 of the output terminal X_{2.0} and the input/output-rule circuit 521 of the output terminal X_{2.1} of the pseudopodia-unit, respectively and independently of each other, and the necessary fluctuations are generated. And, respective output signals from the output terminal X_{2.0} and the output terminal X_{2.1} of the pseudopodia-unit are entered to the bounce-back control logic-circuit 201.

Similarly, through an inverter 430 and an inverter 431, an output terminal of the double-input NOR gate between the output terminal X_{3.0} and the output terminal X_{3.1} which are responsible for determining the value of the variable x₃ is entered to both of a second input terminal of the input/output-rule circuit 530 of the output terminal X_{3.0} and a second input terminal of the input/output-rule circuit 531 of the output terminal X_{3.1}, and inverted signals of the bounce-back signals L_{3.0} and the bounce-back signals L_{3.1} are entered to first input terminals of the input/output-rule circuit 530 of the output terminal X_{3.0} and the input/output-rule circuit 531 of the output terminal X_{3.1}, respectively and independently of each other, and the respective necessary fluctuations are generated. And, respective output signals from the output terminal X_{3.0} and the output terminal X_{3.1} of the pseudopodia-unit are entered to the bounce-back control logic-circuit 201.

Even similarly, an output terminal of the double-input NOR gate between the output terminal X_{4.0} and the output terminal X_{4.1} which are responsible for determining the value of the variable x₄ is entered to both of a second input terminal of the input/output-rule circuit 540 of the output terminal X_{4.0} and a second input terminal of the input/output-rule circuit 541 of the output terminal X_{4.1}, and through an inverter 440 and an inverter 441, inverted signals of the bounce-back signals L_{4.0} and the bounce-back signals L_{4.1} are entered to first input terminals of the input/output-rule circuit 540 of the output terminal X_{4.0} and the input/output-rule circuit 541 of the output terminal X_{4.1}, respectively and independently of each other, and the necessary fluctuations are generated. And, respective output signals from the output terminal X_{4.0} and the output terminal X_{4.1} of the pseudopodia-unit are entered to the bounce-back control logic-circuit 201. In this way, the independent inverted signals of the bounce-back signals L_{1.0}, L_{1.1}, . . . , L_{4.0}, L_{4.1} are entered to the first input terminals of the input/output-rule circuits of the octuple pseudopodia-units, respectively and independently of each other, and the necessary fluctuations are generated, thereby changing the circuit states of each of the corresponding input/output-rule circuits. And, similarly to phenomenon in which the single-celled amoeba, surviving in the natural world, changes the length of legs configured to adapt to environment, the output signals from of the output terminals X_{1.0}, X_{1.1}, . . . , X_{4.0}, X_{4.1} of the pseudopodia-unit, which implement the electronic circuit mimicking the amoeba, are changed by the bounce-back signals L_{1.0}, L_{1.1}, . . . , L_{4.0}, L_{4.1}. Thus, the optimization problem of complex combination can be solved at high speed by an algorithm of a bio-inspired computer.

In addition, as a matter of course, the present invention shall include various subject matters in which the respective features explained in the first and second embodiments are arbitrarily applied, or alternatively, the present invention shall include various embodiments which are not described here. Therefore, the technical scope of the present invention is determined only by the “technical features specifying the invention” construed from the scope of claims, if the determined technical feature that can be interpreted and construed from the claims is appropriate from the contents of description.

What is claimed is:

1. A pulse generator comprising:
an output circuit connected between a higher-potential power-supply and a lower-potential power-supply, the output circuit is implemented by a resistor-connected complementary transistor-circuit including:
a CMOS inverter, and
a resistive element connected in series to the CMOS inverter; and
a voltage source for supplying an input voltage to the CMOS inverter, the input voltage swings in a span including at least a simultaneous-conduction regime of the CMOS inverter, with respect to a swing-center potential set to an inverter threshold as a reference,
wherein shoot-through currents flowing in the CMOS inverter is represented as a triangle in a current versus voltage characteristic diagram of the CMOS inverter, in which values of the input voltage to the CMOS inverter is indicated on a voltage axis of the current versus voltage characteristic diagram, a maximum value of the shoot-through current is defined as a height of the triangle, the inverter threshold is defined as a voltage providing the maximum of the shoot-through current, and the simultaneous-conduction regime is defined as a length of a bottom side of the triangle,
wherein a resistance value of the resistive element is selected such that a potential drop by the shoot-through current when the maximum value of the shoot-through current flows through the resistive element provide a deviation of the input voltage from the simultaneous-conduction regime, and
by repeating process of conductions and interruptions of the shoot-through current, a train of spike-shaped pulses is delivered from the output circuit.

2. The pulse generator of claim 1, wherein a value of the swing-center potential depends on a variation of the resistance value of the resistive element.

3. The pulse generator of claim 1, wherein a value between ⅕ and 1/15 of the simultaneous-conduction regime is set as an effective drive span for the CMOS inverter.

4. The pulse generator of claim 2, wherein a value between ⅕ and 1/15 of the simultaneous-conduction regime is set as an effective drive span for the CMOS inverter.

5. The pulse generator of claim 1, wherein the voltage source alters the input voltage beyond the simultaneous-conduction regime, in an alternating speed slower than a time constant of the CMOS inverter, and at a timing when a potential of the input voltage is plunged into the simultaneous-conduction regime, the conduction and interruption of the shoot-through current are made to be repeated, and only in a time period in which the input voltage belongs to an oscillation-drive active range defined in the simultaneous-conduction regime, the train of spike-shaped pulses is delivered from the output circuit.

6. The pulse generator of claim 2, wherein the voltage source alters the input voltage beyond the simultaneous-conduction regime, in an alternating speed slower than a time constant of the CMOS inverter, and at a timing when a potential of the input voltage is plunged into the simultaneous-conduction regime, the conduction and interruption of the shoot-through current are made to be repeated, and only in a time period in which the input voltage belongs to an oscillation-drive active range defined in the simultaneous-conduction regime, the train of spike-shaped pulses is delivered from the output circuit.

7. The pulse generator of claim 3, wherein the voltage source alters the input voltage beyond the simultaneous-conduction regime, in an alternating speed slower than a time constant of the CMOS inverter, and at a timing when a potential of the input voltage is plunged into the simultaneous-conduction regime, the conduction and interruption of the shoot-through current are made to be repeated, and only in a time period in which the input voltage belongs to an oscillation-drive active range defined in the simultaneous-conduction regime, the train of spike-shaped pulses is delivered from the output circuit.

8. The pulse generator of claim 4, wherein the voltage source alters the input voltage beyond the simultaneous-conduction regime, in an alternating speed slower than a time constant of the CMOS inverter, and at a timing when a potential of the input voltage is plunged into the simultaneous-conduction regime, the conduction and interruption of the shoot-through current are made to be repeated, and only in a time period in which the input voltage belongs to an oscillation-drive active range defined in the simultaneous-conduction regime, the train of spike-shaped pulses is delivered from the output circuit.

9. The pulse generator of claim 1, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

10. The pulse generator of claim 2, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

11. The pulse generator of claim 3, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

12. The pulse generator of claim 4, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

13. The pulse generator of claim 5, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

14. The pulse generator of claim 6, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

15. The pulse generator of claim 7, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.

16. The pulse generator of claim 8, wherein the output circuit further includes another CMOS inverter to implement the resistor-connected complementary transistor-circuit, configured to construct a double stage circuit in which CMOS inverters are connected in parallel in a shape of ladder, and the input voltage is supplied to the input terminal of the CMOS inverter at a first stage.
